(19) United States
(12) Patent Application Publication
(10) Pub. No.: US 2009/0000652 A1
(43) Pub. Date: Jan. 1, 2009

(54) Thermoelectric Structures Including Bridging Thermoelectric Elements

(75) Inventors: Jesko von Windheim, Wake Forest, NC (US); Randall G. Alley, Raleigh, NC (US)

Correspondence Address: MYERS BIGEL SIBLEY & SAJOVEC, PO BOX 37428, RALEIGH, NC, 27627, US

(73) Assignee: Nextreme Thermal Solutions, Inc.

(21) Appl. No.: 12/146,012

(22) Filed: Jun. 25, 2008

Related U.S. Application Data
(60) Provisional application No. 60/946,227, filed on Jun. 26, 2007.

(51) Int. Cl. H01L 35/02

(52) U.S. Cl. 136/230

(57) ABSTRACT

A thermoelectric structure may include first and second thermally conductive layers. The first and second thermally conductive layers may be laterally spaced apart in a direction parallel with respect to surfaces of the first and second thermally conductive layers so that a gap is defined between edges of the first and second thermally conductive layers. A thermoelectric element may bridge the gap between the first and second thermally conductive layers, and the thermoelectric element may include a thermoelectric material on respective surface portions of the first and second thermally conductive layers.

### RELATED APPLICATION

The present application claims the benefit of priority from U.S. Provisional Application No. 60/946,227 entitled “Platform Thermoelectric Cooler” filed Jun. 26, 2007, the disclosure of which is hereby incorporated herein in its entirety by reference.

### FIELD OF THE INVENTION

The present invention relates to the field of electronics, and more particularly, to thermoelectric structures.

### BACKGROUND

Thermoelectric materials may be used to provide cooling and/or power generation according to the Peltier effect. Thermoelectric materials are discussed, for example, in the reference by Venkatasubramanian et al. entitled “Phonon-Blocking Electron-Transmitting Structures” (18^{th} International Conference On Thermoelectrics, 1999), the disclosure of which is hereby incorporated herein in its entirety by reference.

Application of solid state thermoelectric cooling may be expected to improve the performance of electronics and sensors such as, for example, RF receiver front-ends, infrared (IR) imagers, ultra-sensitive magnetic signature sensors, and/or superconducting electronics. Bulk thermoelectric materials typically based on p-BiₓSb₂₋ₓTe₃ and n-Bi₂Te₃₋ₓSeₓ alloys may have figures-of-merit (ZT) and/or coefficients of performance (COP) which result in relatively poor thermoelectric device performance.

The performance of a thermoelectric device may be a function of the figure(s)-of-merit (ZT) of the thermoelectric material(s) used in the device, with the figure-of-merit being given by:

ZT=(α²Tσ/K_{T}), (equation 1)

where α, T, σ, K_{T} are the Seebeck coefficient, absolute temperature, electrical conductivity, and total thermal conductivity, respectively. The material-coefficient Z can be expressed in terms of lattice thermal conductivity (K_{L}), electronic thermal conductivity (K_{c}) and carrier mobility (μ), for a given carrier density (ρ) and the corresponding α, yielding equation (2) below:

Z=α²σ/(K_{L}+Kₑ)=α²/K_{L}[/(μρq)+L₀T)], (equation 2)

where, L₀ is the Lorenz number (approximately 1.5×10⁻⁸V²/K² in non-degenerate semiconductors). State-of-the-art thermoelectric devices may use alloys, such as p-BiₓSb₂₋ₓTe_{3-y}Se_{y} (x≈0.5, y≈0.12) and n-Bi₂(Se_{y}Te_{1-y})₃ (y≈0.05) for the 200 degree K to 400 degree K temperature range. For certain alloys, K_{L} may be reduced more strongly than μleading to enhanced ZT.

A ZT of 0.75 at 300 degree K in p-type BiₓSb₂₋ₓTe₃ (x≈1) was reported forty years ago. See, for example Wright, D. A., Nature vol. 181, pp. 834 (1958). Since then, there has been relatively modest progress in the ZT of thermoelectric materials near 300 degree K (i.e., room temperature). A ZT of about 1.14 at 300 degree K for bulk p-type (Bi₂Te₃)_{0.25} (Sb₂Te₃)_{0.72} (Sb₂Se₃)_{0.03} alloy has been discussed for example, in the reference by Ettenberg et al. entitled “A New N-Type And Improved P-Type Pseudo-Ternary (Bi₂Te₃)(Sb₂Te₃)(Sb₂Se₃) Alloy For Peltier Cooling,” (Proc. of 15^{th} Inter. Conf. on Thermoelectrics, IEEE Catalog. No. 96TH8169, pp. 52-56, 1996), the disclosure of which is hereby incorporated herein in its entirety by reference.

### SUMMARY

According to some embodiments of the present invention, a thermoelectric structure may include first and second thermally conductive layers and a thermoelectric element. The first and second thermally conductive layers may be laterally spaced apart in a direction parallel with respect to surfaces of the first and second thermally conductive layers so that a gap is defined between edges of the first and second thermally conductive layers. The thermoelectric element may bridge the gap between the first and second thermally conductive layers, and the thermoelectric element may include a thermoelectric material on respective surface portions of at least one of the first and second thermally conductive layers.

The thermoelectric element may include a continuous segment of the thermoelectric material bridging the gap between the first and second thermally conductive layers. According to other embodiments of the present invention, the thermoelectric element may include a first segment of thermoelectric material on the first thermally conductive layer, a second segment of thermoelectric material on the second thermally conductive layer, and a conductive layer on the first and second segments of the thermoelectric material. More particularly, the first and second segments of the thermoelectric material may have a same conductivity type, and the first and second segments of the thermoelectric material may be separated by the gap.

The thermoelectric element may be a first thermoelectric element and the thermoelectric material may be a first thermoelectric material having a first conductivity type. In addition, a second thermoelectric element may bridge the gap between the first and second thermally conductive layers. The second thermoelectric element may include a second thermoelectric material having a second conductivity type on second surface portions of at least on of the first and second thermally conductive layers, and the first and second conductivity types may be different.

The first and second thermoelectric elements may be electrically coupled in series so that current flows through the first thermoelectric element in a direction from the first thermally conductive layer toward the second thermally conductive layer while current flows through the second thermoelectric element in a direction from the second thermally conductive layer toward the first thermally conductive layer. Moreover, the first thermally conductive layer may define a recess and the second thermally conductive layer may define an extension extending into the recess so that the gap extends around the extension between the extension and the recess. In addition, the first and second thermoelectric elements may bridge the gap between the first and second thermally conductive layers on opposite sides of the extension.

The first and second thermally conductive layers may be thermally isolated, and/or surfaces of the first and second thermally conductive layers may be substantially coplanar. Moreover, the second thermally conductive layer may surround the first thermally conductive layer. In addition, the thermoelectric element may be a first thermoelectric element, and a second thermoelectric element may bridge the gap between the first and second thermally conductive layers, with the first and second thermoelectric elements being on opposites sides of the first thermally conductive layer.

The gap between the first and second thermally conductive layers may be free of the thermoelectric material. The first and second thermally conductive layers may be supported on a same substrate, and a cavity may be defined between portions of the first thermally conductive layer and the substrate. A thermally insulating layer may provide mechanical coupling between the first thermally conductive layer and the substrate with the cavity being further defined between portions of the thermally insulating layer and the substrate. The thermally insulating layer may include a layer of a thermally insulating material such as silicon oxide, silicon nitride, magnesium oxide, and/or polyimide. An electrically active component may be provided on the first thermally conductive layer so that the electrically active component and the thermoelectric element are on a same surface of the first thermally conductive layer.

The gap may be a first gap and the thermoelectric element may be a first thermoelectric element. In addition, a third thermally conductive layer may be laterally spaced apart from the second thermally conductive layer in the direction parallel with respect to surfaces of the first, second, and third thermally conductive layers so that the second thermally conductive layer is between the first and third thermally conductive layers and so that a second gap is defined between edges of the second and third thermally conductive layers. A second thermoelectric element may bridge the gap between the second and third thermally conductive layers, and the second thermoelectric element may include a thermoelectric material on respective surface portions of the second and third thermally conductive layers.

The first thermally conductive layer may include a semiconductor substrate. Moreover, first and second electronic substrates may be mechanically coupled to opposite sides of the first thermally conductive layer. A controller may be electrically coupled to the thermoelectric element, and the controller may be configured to generate an electrical current through the thermoelectric element to provide thermoelectric cooling and/or heating of the first thermally conductive layer. An electrical load coupled to the thermoelectric element may be configured to receive electrical power from the thermoelectric element responsive to a temperature gradient between the first and second thermally conductive layers. A controller may be electrically coupled to the thermoelectric element, and the controller may be configured to detect a temperature of the first thermally conductive layer and/or to detect a temperature gradient between the first and second thermally conductive layers responsive an electrical characteristic of the thermoelectric element.

### BRIEF DESCRIPTION OF THE DRAWINGS

FIGS. 1A and 1B are cross sectional views illustrating thermoelectric structures including bridging thermoelectric elements according to some embodiments of the present invention.

FIG. 2 is a plan view of a thermoelectric structure including a pair of bridging thermoelectric elements of opposite conductivity types according to some embodiments of the present invention.

FIG. 3 is a plan view illustrating a thermoelectric module including an array of p-type and n-type semiconductor thermoelectric elements between thermally conductive headers H1 and H2.

FIG. 4 is a cross-sectional view of a thermoelectric structure including bridging thermoelectric elements on opposite sides of a thermally conductive layer according to some embodiments of the present invention.

FIGS. 5A and 5B are respective cross sectional and plan views of a thermoelectric structure including bridging thermoelectric elements on a same side of a thermally conductive layer according to some embodiments of the present invention.

FIG. 6 is a plan view of a thermoelectric element from FIGS. 5A and 5B according to embodiments of the present invention.

FIGS. 7A and 7B are tables providing material parameters and device dimensions for a modeled structure of FIGS. 5A, 5B, and 6 according to some embodiments of the present invention.

FIG. 8 is a table illustrating thermoelectric performance characteristics for a modeled structure of FIGS. 5A, 5B, and 6 according to some embodiments of the present invention.

FIG. 9 is a graph illustrating load lines at different currents for a modeled structure of FIGS. 5A, 5B, and 6 according to embodiments of the present invention.

FIG. 10A is a plan view of a thermoelectric structure including bridging thermoelectric elements on interdigitated fingers of thermally conductive layers according to some embodiments of the present invention.

FIG. 10B is an enlarged cross sectional view illustrating a finger of a thermally conductive layer of FIG. 10A according to some embodiments of the present invention.

FIG. 11 is a plan view of a thermoelectric structure including bridging thermoelectric elements of opposite conductivity types on interdigitated fingers of thermally conductive layers according to some embodiments of the present invention.

FIGS. 12 and 13 are tables illustrating parameters used to model performance of thermoelectric structures of FIGS. 10A and 11 according to some embodiments of the present invention.

FIGS. 14A and 14B are respective cross-sectional and plan views of a thermoelectric structure including bridging thermoelectric elements of opposite conductivity types around a circular thermally conductive layer according to some embodiments of the present invention.

FIG. 15 is a cross sectional view illustrating an alternative cavity/support structure that may be provided for structures of FIGS. 14A and 14B according to some embodiments of the present invention.

FIG. 16 is a plan view of a cascaded thermoelectric structure including bridging thermoelectric elements of opposite conductivity types bridging staged thermally conductive layers according to some embodiments of the present invention.

FIG. 17 is a table illustrating performance characteristics of a thermoelectric cooler having a structure as illustrated in FIGS. 14A and 14B according to some embodiments of the present invention.

FIGS. 18 and 21 are cross sectional views illustrating three dimensional electronic structures including stacks of integrated circuit devices according to still further embodiments of the present invention.

FIG. 19 is a cross sectional view illustrating an implementation of a cascaded thermoelectric structure with thermally conductive layers supported by relatively thin electrically and thermally insulating layers according to some embodiments of the present invention.

FIG. 20 is a plan view of a cascaded thermoelectric cooling structure including a single current path for thermoelectric elements of all stages according to some embodiments of the present invention.

### DETAILED DESCRIPTION

The present invention is described more fully hereinafter with reference to the accompanying drawings, in which embodiments of the present invention are shown. This invention may, however, be embodied in many different forms and should not be construed as limited to the embodiments set forth herein. Rather, these embodiments are provided so that this disclosure will be thorough and complete, and will fully convey the scope of the present invention to those skilled in the art. In the drawings, the sizes and relative sizes of layers and regions may be exaggerated for clarity. Like numbers refer to like elements throughout.

It will be understood that when an element or layer is referred to as being “on”, “connected to” or “coupled to” another element or layer, it can be directly on, connected or coupled to the other element, or layer or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly. Also, as used herein, “lateral” refers to a direction that is substantially orthogonal to a vertical direction.

The terminology used herein is for the purpose of describing particular embodiments only, and is not intended to be limiting of the present invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a structure illustrated with angular features will, typically, have rounded or curved features. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. Accordingly, these terms can include equivalent terms that are created after such time. It will be further understood that terms, such as those defined in commonly used dictionaries, should be interpreted as having a meaning that is consistent with their meaning in the present specification and in the context of the relevant art, and will not be interpreted in an idealized or overly formal sense unless expressly so defined herein. All publications, patent applications, patents, and other references mentioned herein are incorporated by reference in their entirety.

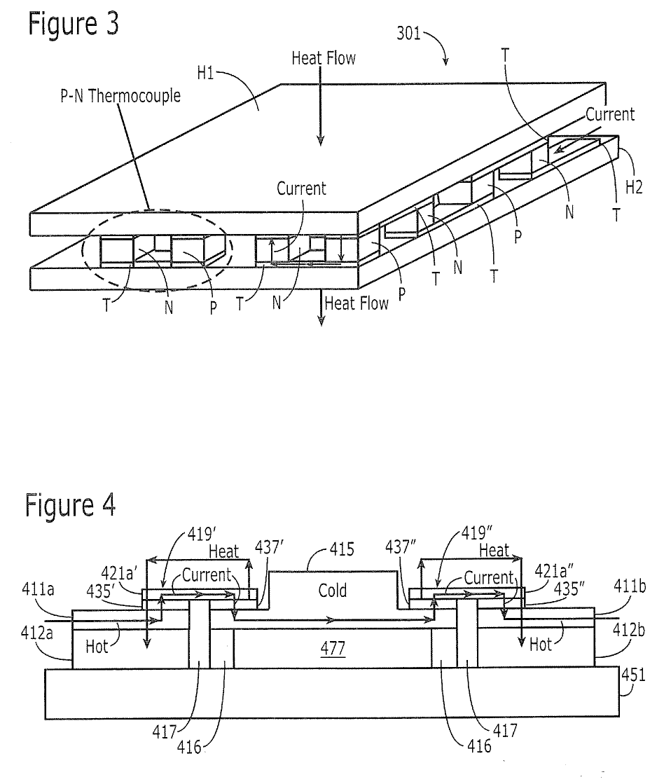

Thermoelectric devices may be used to provide thermoelectric cooling, thermoelectric heating, thermoelectric power generation, and/or thermoelectric sensing according to the Peltier/Seebeck effect. A thermoelectric module 301, for example, may include an array of p-type and n-type semiconductor thermoelectric elements P and N (also referred to as thermoelectric pellets) electrically coupled in series and thermally coupled in parallel between thermally conductive headers H1 and H2 as shown in the plan view of FIG. 3. Moreover, electrically conductive traces T on the headers H1 and H2 may provide electrical coupling between p-type and n-type thermoelectric elements P and N so that an electrical current through the p-type thermoelectric elements P is provided in a first direction (e.g., in a direction from header H1 toward header H2) while the same electrical current through the n-type thermoelectric elements N is provided in a second direction (e.g., in a direction from header H2 toward header H1) opposite the first direction.

In the thermoelectric module 301 of FIG. 3, heat may be pumped from header H1 to header H2 responsive to a current through the serially coupled thermoelectric elements P and N thereby cooling header H1 and/or a component thermally coupled to header H1. By reversing the current, heat may be pumped from header H2 to header H1 thereby heating header H1. Thermoelectric structures are discussed, for example, in U.S. Patent Publication Nos. 20060289052 (entitled “Methods Of Forming Thermoelectric Devices Including Conductive Posts And/Or Different Solder Materials And Related Methods And Structures”), 20060289050 (entitled “Methods Of Forming Thermoelectric Devices Including Electrically Insulating Matrixes Between Conductive Traces And Related Structures”), 20060086118 (entitled “Thin Film Thermoelectric Devices For Hot-Spot Thermal Management In Microprocessors And Other Electronics”), 20070089773 (entitled “Methods Of Forming Embedded Thermoelectric Coolers With Adjacent Thermally Conductive Fields And Related Structures”), and 20070215194 (entitled “Methods Of Forming Thermoelectric Devices Using Islands Of Thermoelectric Material And Related Structures”), the disclosures of which are hereby incorporated herein in their entirety by reference.

Thermoelectric elements P and N may be provided using semiconductor thin-film deposition techniques, and the module 301 of FIG. 3 may be fabricated using micro-fabrication techniques. For example, thin-films of p-type and n-type thermoelectric materials (e.g., bismuth telluride or Bi₂Te₃) may be epitaxially grown on respective substrates and then diced to provide substantially single crystal p-type and n-type thermoelectric elements P and N that are then soldered to respective traces T in the module 301 of FIG. 3. In an alternative, modules having the structure of FIG. 3 may be provided using bulk (e.g., thicker and non-crystalline) thermoelectric elements. By using thin-film substantially single crystal thermoelectric elements, however, a size of module 301 may be reduced and performance may be improved.

With the structure of module 301, thermoelectric elements P and N may bear thermal stress, mechanical stress, and electrical stress. Thermoelectric elements P and N, however, may be relatively brittle so that mechanical stress thereon may reduce a mechanical reliability of the device. Moreover, if a temperature gradient is generated between headers H1 and H2 so that header H1 is cooler than header H2, a bowing/flexing of the module 301 may occur as a result of differences in thermal expansion (e.g., warmer header H2 may expand while cooler header H1 contracts), and this bowing/flexing may limit a useful lifetime of the module and/or increase a difficulty of implementation. For example, bowing/flexing of module 301 may result in mechanical failure of one or more of thermoelectric elements P and N.

In addition, a number of degrees of freedom in design to affect performance may be relatively limited. For example, a width and/or thickness of thermoelectric elements P and N may be varied, a number of thermoelectric elements P and N may be varied, and/or a spacing of thermoelectric elements P and N may be varied. Even these variables may be constrained, however, because thermal stresses may constrain how closely thermoelectric elements may be placed relative to how thick/tall the thermoelectric elements are.

According to some embodiments of the present invention, bridging thermoelectric elements may be provided bridging surfaces of substantially co-planar thermally conductive layers (also referred to as thermally conductive headers). By providing mechanical support for the thermally conductive layers (other than the bridging thermoelectric elements), mechanical stress on the thermoelectric elements may be reduced, and bowing/flexing of the thermoelectric module may be reduced. Moreover, an ease of manufacture may be improved and/or a thickness of the resulting module may be reduced because a sandwiching of thermoelectric elements between thermally conductive headers may not be required. In addition, a thermal/mechanical stress resulting in differences in thermally conductive layers (due to one thermally conductive layer being heated/cooled relative to the other) may be reduced by providing that adjacent edges of heated and cooled thermally conductive layers may maintain substantially a same gap therebetween. For example, an edge of a heated thermally conductive layer may expand toward the cooled thermally conductive layer while an adjacent edge of the cooled thermally conductive layer may contract away from the heated thermally conductive layer to maintain substantially a same gap therebetween.

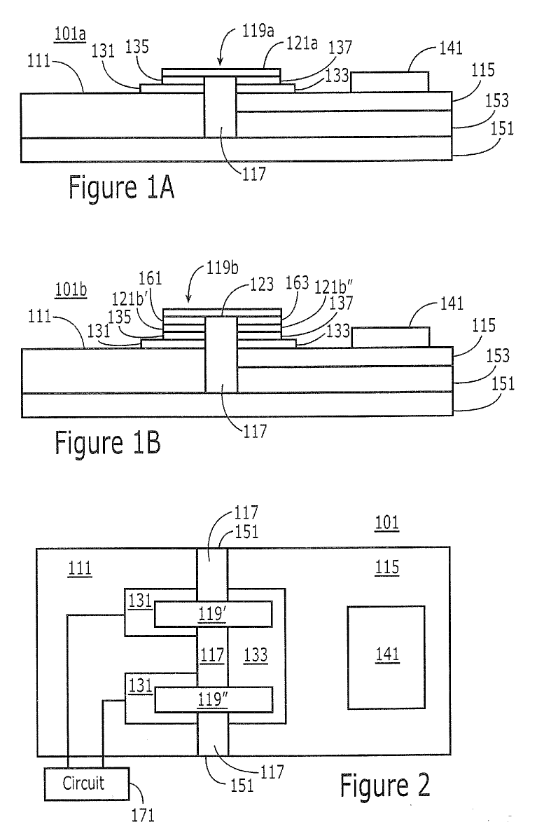

Thermoelectric structures 101a and 101b according to some embodiments of the present invention may include respective bridging thermoelectric elements 119a and 119b as shown in FIGS. 1A and 1B. In each of FIGS. 1A and 1B, the bridging thermoelectric elements 119a and 119b may be used to provide cooling of thermally conductive layer 115, heating of thermally conductive layer 115, sensing of a thermal gradient between thermally conductive layers 111 and 115, and/or power generation responsive to a thermal gradient between thermally conductive layers 111 and 115. In each of FIGS. 1A and 1B, thermally conducive layers 111 and 115 may be mechanically supported on a same substrate 151, and a gap 117 may be provided between thermally conductive layers 111 and 115. Gap 117 may thus provide thermal isolation between thermally conductive layers 111 and 115. Gap 117, for example, may provide an air (or other gas) or a vacuum gap, or gap 117 may be filled with a thermally insulating material.

Thermally conductive layer 115 may be thermally isolated from substrate 151 by providing a thermally insulating structure 153 between substrate 151 and thermally conductive layer 115, and/or substrate 151 may provide thermal isolation between thermally conductive layers 111 and 115. Thermally insulating structure 153, for example, may include: a continuous layer of a thermally insulating material; pillars, posts, or other non-continuous support structures providing cavities and relatively high thermal resistance support structures between thermally conductive layer 115 and substrate 151; and/or thermally conductive layer 115 may be supported by bridging thermoelectric elements and/or other bridging structures so that thermally conductive layer 115 and substrate 151 may be separated by a continuous cavity therebetween. Substrate 151 may provide thermal isolation between thermally conductive layers 111 and 115, for example, by providing that the substrate 151 or portions thereof includes an insulating material, and/or by otherwise providing a relatively high electrical resistance though substrate 151 between thermally conductive layers 111 and 115. For example, a thickness of portions of substrate 151 at gap 117 may be reduced, and/or portions of substrate 151 at gap 117 may be patterned to provide a serpentine pattern that increases a thermal path (thereby increasing thermal resistance) through substrate 151 across gap 117.

Thermally conductive layers 111 and/or 115 may include layers of electrically insulating thermally conductive materials (such as passivated copper, gold coated aluminum nitride, diamond, silicon, etc.), or thermally conductive layers 111 and/or 115 may include layers of an electrically and thermally conductive material (such as copper) with a thin electrically insulating layer (such as silicon oxide, silicon nitride, metal oxide, etc.) thereon to provide electrical isolation for metal traces 131 and/or 133. Moreover, an electrically active component 141 or other structure may be provided on thermally conductive layer 115 to provide temperature control and/or monitoring thereof. Electrically active component 141, for example, may be an optical component (such as a light emitting diode, a laser diode, etc.), an integrated circuit electronic device (such as a microprocessor), a power electronic device (such as a power transistor, a diode, etc.), a sensor, or other electrically active component or structure that generates heat, and the thermally conductive layers 111 and 115 and thermoelectric elements may be configured to provide temperature control and/or cooling for component 141. According to other embodiments of the present invention, thermally conductive layer 115 may include a semiconductor substrate of a semiconductor electronic device so that a separate thermally conductive layer 115 and component 141 are not required. More generally, the thermally conductive layer 115 may be a device/structure (or a portion thereof) to be cooled/heated so that a separate component 141 may be omitted.

By providing bridging thermoelectric elements 119a and/or 119b as shown in FIGS. 1A and 1B, surfaces of thermally conductive layers 111 and 115 may be substantially coplanar, thereby reducing a height of the resulting structures. Moreover, thermally conductive layers 111 and 115 may be formed using integrated circuit fabrication and/or microelectromechanical fabrication techniques such as thin film deposition and/or photolithographic patterning techniques. Bridging thermoelectric elements 119a and/or 119b (and/or portions thereof) may be formed on thermally conductive layers 111 and 115, for example, using thin film deposition (e.g., sputtering, evaporation, etc.) and/or photolithographic patterning techniques, or thermoelectric elements 119a and/or 119b (and/or portions thereof) may be formed separately and then bonded (e.g., using solder) to thermally conductive layers 111 and 115.

In FIG. 1A, for example, a sacrificial layer may be provided in the gap 117, and the continuous segment 121a of thermoelectric material may be deposited (e.g., using sputtering, evaporation, etc.) directly on the metal traces 131 and 133 and on the sacrificial layer and then patterned (so that solder layers 135 and 137 may be omitted). After forming/patterning the continuous segment 121a of thermoelectric material, the sacrificial layer may be removed from the gap 117. In FIG. 1B, for example, the segments 121b′/121b″ of thermoelectric material and conductive layer 123 may be similarly deposited (e.g., using sputtering, evaporation, etc.) and patterned (so that solder layers 135/137/161/163 may be omitted).

As shown in FIGS. 1A and 1B, a thermoelectric structure 101a and/or 101b may include thermally conductive layers 111 and 115 that are laterally spaced apart in a direction that is parallel with respect to surfaces of the thermally conductive layers 111 and 115. Accordingly, a gap 117 may be defined between edges of the thermally conductive layers 115 and 117, and a thermoelectric element 119a or 119b may bridge the gap 117 between thermally conductive layers 111 and 115.

As shown in FIG. 1A, thermoelectric element 119a may include a thermoelectric material on respective surface portions of thermally conductive layers 111 and 115. More particularly, thermoelectric element 119a may include a continuous segment 121a of the thermoelectric material bridging the gap 117 between the thermally conductive layers 111 and 115, and the gap 117 may be free of the thermoelectric material between the thermally conductive layers 111 and 115. Thermoelectric element 119a may be bonded to metal traces 131 and 133 using respective solder layers 135 and 137. While not separately shown in FIG. 1A, barrier layers (e.g., layers including nickel), passivation layers (e.g., layers including gold), and/or adhesion layers (e.g., layers including titanium and/or chromium) may be included between solder layers 135/137 and respective metal traces 131/133 and/or between solder layers 135/137 and the continuous segment 121a of the thermoelectric material.

As shown in FIG. 1B, thermoelectric element 119b may include a first segment 121b′ of thermoelectric material on thermally conductive layer 111, a second segment 121b″ of thermoelectric material on thermally conductive layer 115, and a conductive layer 123 (e.g., a copper or other metal layer) on segments 121b′ and 121b″ of the thermoelectric material. Moreover, segments 121b′ and 121b″ of the thermoelectric material may have a same conductivity type, and segments 121b′ and 121b″ of the thermoelectric material may be separated by gap 117.

Segments 121b′ and 121b″ may be bonded to metal traces 131 and 133 using respective solder layers 135 and 137, and/or segments 121b′ and 121b″ may be bonded to conductive layer 123 using respective solder layers 161 and 163. While not separately shown in FIG. 1B, barrier layers (e.g., layers including nickel), passivation layers (e.g., layers including gold), and/or adhesion layers (e.g., layers including titanium and/or chromium) may be included between solder layers 135/137 and respective metal traces 131/133 and/or between solder layers 135/137 and respective segments 121b′ and 121b″. Similarly, barrier layers (e.g., layers including nickel), passivation layers (e.g., layers including gold), and/or adhesion layers (e.g., layers including titanium and/or chromium) may be included between solder layers 161/163 and conductive layer 123 and/or between solder layers 161/163 and respective segments 121b′ and 121b″.

In the structure of FIG. 1B, four thermoelectric to metal contacts (e.g., contacts between conductive layer 123 and segments 121b′/121b″ and contacts between segments 121b′/121b″ and metal traces 131/133) may be provided for each thermoelectric element 119b (as opposed to two thermoelectric to metal contacts for each thermoelectric element 119a of FIG. 1A). In comparing the structures of FIGS. 1A and 1B, thermoelectric element 119a of FIG. 1A may provide reduced contact resistance because only two contacts are provided between segment 121a of thermoelectric material and metal traces 131 and 133 while thermoelectric element 119b of FIG. 1B may have four contacts between segments 121b′/121b″, metal traces 131/133, and conductive layer 123. In contrast, thermoelectric element 119b may provide reduced resistance through segments 121b′/121b″ of thermoelectric material because a length of an electrical path through segments 121b′/121b″ may be reduced relative to a length of an electrical path through segment 121a. The structure of thermoelectric element 119b may provide increased power pumping capability while pumping heat laterally. In addition, the thermoelectric element 119b of FIG. 1B may provide improved mechanical robustness because the thermoelectric material is not required to bridge the gap 117, with mechanical bridging being provided instead by a metal layer. Moreover, thermoelectric element 119b may allow an increased distance between thermally conductive layers 111 and 115 (e.g., an increased width of gap 117) because an increased length of metal layer 123 may not significantly increase a total resistance of thermoelectric element 119b. A total electrical resistance of a thermoelectric element may include a sum of resistances due to thermoelectric-to-metal contacts, resistances due to current flow through the thermoelectric material, and resistances due to current flow through metal portions of the thermoelectric element.

According to still other embodiments of the present invention, thermoelectric element 119b of FIG. 1B may be provided with one or the other of segments 121b′ or 121b″ of thermoelectric material (but not both). For example, metal layer 123 may be electrically coupled to metal trace 133 through a metal interconnection (without segment 121b″) while maintaining segment 121b′, or metal layer 123 may be electrically coupled to metal trace 131 through a metal interconnection (omitting segment 121b′) while maintaining segment 121b″. By omitting one of the segments 121b′ or 121b″ (while maintaining the other) in the structure of FIG. 1B, electrical resistances may be reduced (by reducing a number of thermoelectric material to metal contacts and/or by reducing a length of a current path through thermoelectric material).

FIG. 2 is a plan view of a thermoelectric structure 101 including a pair of bridging thermoelectric elements 119′ and 119″ of opposite conductivity types (e.g., n-type and p-type). More particularly, bridging thermoelectric elements 119′ and 119″ are thermally coupled in parallel between thermally conductive layers 111 and 115, and bridging thermoelectric elements 119′ and 119″ are electrically coupled in series between terminals of electrical circuit 171. In the structure of FIG. 2, each of bridging thermoelectric elements 119′ and 119″ may be implemented using a continuous segment of thermoelectric material 121a as discuss above with respect to FIG. 1A, or using separate segments of thermoelectric material 121b′ and 121b″ (or a single segment of thermoelectric material) and a bridging conductive layer 123 as discussed above with respect to FIG. 1B.

With thermoelectric elements 119′ and 119″ electrically coupled in series, electrical current flows through thermoelectric element 119′ in a direction from thermally conductive layer 111 toward thermally conductive layer 115 while current flows through the second thermoelectric element in a direction from thermally conductive layer 115 toward thermally conductive layer 111. Accordingly, both thermoelectric elements 119′ and 119″ (of opposite conductivity types) may pump heat from thermally conductive layer 115 to thermally conductive layer 111 or from thermally conductive layer 111 to thermally conductive layer 115 depending on a direction of electrical current through thermoelectric elements 119′ and 119″. While only two bridging thermoelectric elements 119′ and 119″ are shown by way of example, any number of thermoelectric elements may be provided using structures such as that illustrated in FIG. 2.

Electrical circuit 171 may thus be configured to provide temperature control (e.g., cooling and/or heating) for thermally conductive layer 115 and/or for electrically active component 141 thereon, to capture/consume electrical power generated by thermoelectric elements 119′ and 119″, and/or to detect a temperature and/or a temperature gradient between thermally conductive layers 111 and 115. Electrical circuit 171, for example, may include a controller electrically coupled to thermoelectric elements 119′ and 119″, wherein the controller is configured to generate an electrical current through thermoelectric elements 119′ and 119″ to provide thermoelectric cooling and/or heating of the first thermally conductive layer 115 and/or component 141. Electrical circuit 171 may include an electrical load configured to receive electrical power from thermoelectric elements 119′ and 119″ responsive to a temperature gradient between thermally conductive layers 111 and 115. Electrical circuit 171, for example, may include a device to be charged or powered such as a battery, a capacitor, a charging circuit, a power converter, or other load. Electrical circuit 171 may include a controller configured to detect a temperature of thermally conductive layer 115 and/or to detect a temperature gradient between thermally conductive layers 111 and 115 responsive an electrical characteristic of thermoelectric elements 119′ and 119″ (such as a current/voltage generated by and/or an electrical resistance of the thermoelectric elements).

Thermoelectric structures according to embodiments of the present invention may thus be fabricated using micromachining techniques, and after fabricating structures up to thermally conductive layers 111 and 115, bridging thermoelectric elements 119 and/or elements thereof may be provided thereon using pick and place manufacturing techniques/equipment and/or direct deposition (e.g., sputtering, evaporation, etc.). Moreover, the bridging thermoelectric elements may be implemented using thin-film (substantially single crystal, polycrystalline, amorphous, etc.) thermoelectric material and/or using bulk (amorphous, hot pressed, polycrystalline, etc.) thermoelectric material. A stress born by thermoelectric elements 119′ and/or 119″ may be reduced because each of the thermally conductive layers 111 and 115 may be separately supported on substrate 151.

By providing thermally conductive layers 111 and 115 of a same material, thermal stress during thermoelectric cooling/heating may be reduced. More particularly, the heated thermally conductive layer may expand in a direction toward the cooled thermally conductive layer while the cooled thermally conductive layer may contract in a direction away from the heated thermally conductive layer, with the expansion and contraction occurring at approximately the same rate. Accordingly, a width of the gap 117 may remain relatively constant even though one of the thermally conductive layers 111 and 115 is contracting while the other is expanding.

In addition, the use of bridging thermoelectric elements may provide greater flexibility in design. For example, a number of bridging thermoelectric elements, dimensions (e.g., height, length, and/or width) of bridging thermoelectric elements, and/or a size of a temperature controlled platform (e.g., thermally conductive layer 115) may be tailored to specific applications. Moreover, bridging thermoelectric elements may facilitate a lateral (i.e., in a direction parallel with respect to a surface of thermally conductive layer 115) transfer of heat.

As discussed in greater detail below, bridging thermoelectric elements may be implemented in different structures according to embodiments of the present invention. In each of the embodiments discussed below, the bridging thermoelectric elements may be implemented using either the bridging thermoelectric element 119a of FIG. 1A and/or the bridging thermoelectric element 119b of FIG. 1B.

FIG. 4 is a cross-sectional view of a thermoelectric structure including bridging thermoelectric elements 419′ and 419″ of opposite conductivity types on opposite sides of a thermally conductive layer 415 according to some embodiments of the present invention. As shown in FIG. 4, bridging thermoelectric elements 419′ and 419″ may have opposite conductivity types (e.g., n-type and p-type, respectively) and the bridging thermoelectric elements 419′ and 419″ may be electrically coupled in series so that a same electrical current through the bridging thermoelectric elements 419′ and 419″ results in a transfer of heat away from thermally conductive layer 415 to thermally conductive layers 411a and 411b. Moreover, thermally conductive layers 411a and 411b may be separate thermally conductive layers provided on opposite sides of thermally conductive layer 415, or thermally conductive layers 411a and 411b may be different portions of a same thermally conductive layer 411 that (partially or completely) surrounds thermally conductive layer 415. In addition, gaps 417 may provide thermal isolation between thermally conductive layer 415 and thermally conductive layers 411a and 411b, and cavity 477 may provide electrical isolation between thermally conductive layer 415 and substrate 451.

As shown in FIG. 4, thermally conductive layers 411a and 411b may be provided on thermally insulating layers 412a and 412b to provide thermal isolation between thermally conductive layers 411a/411b and substrate 451. According to other embodiments of the present invention, substrate 451 and layers 412a and 412b may comprise a same material. Moreover, thermally conductive layers 411a and 411b may be thermally coupled to a heat sink or other structure providing a thermal ground or otherwise capable of dissipating/sourcing heat. Each of the thermally conductive layers 411a, 411b, and 415 may include a layer of a thermally conductive material such as passivated copper (Cu), gold (Au) coated aluminum nitride (AlN), diamond, silicon, etc. If any of thermally conductive layers 411a, 411b, and/or 415 is also electrically conductive, an electrical current path(s) to/from thermoelectric elements 419′/419″ may be provided therethrough (without requiring separate patterned traces) as shown in FIG. 4. If any of thermally conductive layers 411a, 411b, and/or 415 is electrically insulating (or has an electrically insulating layer thereon), an electrical current path(s) may be provided using an electrically conductive trace(s) on the electrically insulating layer(s).

As further shown in FIG. 4, support structures 416 may support thermally conductive layer 415 relative to substrate 451. Support structures 416 may be relatively narrow (in a lateral dimension parallel with respect to a surface of substrate 451) and/or comprise a thermally insulating material (e.g., silicon oxide, silicon nitride, etc.) to provide thermal isolation between thermally conductive layer 415 and substrate 451. By reducing sizes of support structures 416 in a dimension parallel with respect to a surface of substrate 451, a size of cavity 477 may be increased thereby increasing thermal isolation. Cavity 477 and/or gaps 417 may be filled with a gas (e.g., air), a vacuum, and/or a thermally insulating material. While support structures 416 are shown at edges of thermally conductive layer 415, support structures 416 may be moved toward a more central portion of thermally conductive layer 415 to increase a thermal path through such support structures between thermally conductive layer 415 and thermally conductive layers 411a/411b. According to other embodiments of the present invention, support structures 416 may be omitted so that bridging thermoelectric elements 419′ and 419″ provide mechanical support for thermally conductive layer 415. According to still other embodiments of the present invention, support structures 416 may be omitted with thin thermally insulating layers (e.g., layers of silicon oxide, silicon nitride, magnesium oxide, polyimide, etc.) extending laterally from layers 412a and 412b to support thermally conductive layer 415. According to yet other embodiments of the present invention, a thermal resistance between thermally conductive layers 411a/411b and 415 may be increased by reducing a thickness of portions of substrate 451 thermally coupled between layers 411a/411b and support structures 416, and/or by providing a serpentine thermal path through portions of substrate 451 thermally coupled between layers 411a/411b and support structures 416.

An electrical current through serially coupled bridging thermoelectric elements 419′ and 419″ as shown in FIG. 4 may thus pump heat from thermally conductive layer 415 to thermally conductive layers 411a and 411b. As shown in FIG. 4, thermally conductive layers 411a, 411b, and 415 may be electrically conductive so that separate electrically conductive traces are not required. According to other embodiments of the present invention, one or more of thermally conductive layers 411a, 411b, and/or 415 may be electrically insulating and/or may have an electrically insulating layer thereon so that patterned metal traces may provide electrical coupling between bridging thermoelectric elements.

While not separately shown in FIG. 4, an electrically active component (e.g., an optical component, an integrated circuit electronic device, a power electronic device, a sensor, etc.) or other structure may be provided on and/or coupled to thermally conductive layer 415 to provide cooling/heating thereof, and/or thermally conductive layer 415 may be/include a substrate (e.g., a semiconductor substrate) of such an electrically active component or other structure.

Each of the bridging thermoelectric elements 419′/419″ may include a continuous segment 421a′/421a″ of thermoelectric material bridging gaps 417 and respective solder layers 435′/435″ and 437′/437″ as discussed above with respect to FIG. 1A. According to other embodiments of the present invention, each of the bridging thermoelectric elements 419′/419″ may include separate segments of thermoelectric material on opposite sides of gap(s) 417 (or a single segment of thermoelectric material on only one side) with a conductive layer providing electrical connection across the gaps 417 as discussed above with respect to FIG. 1B. While only two bridging thermoelectric elements 419′ and 419″ are shown by way of example, any number of thermoelectric elements may be provided with platform structures such as those illustrated in FIG. 4.

As discussed above with respect to FIGS. 1A, 1B, and 2, an electrical circuit may be configured to provide temperature control (e.g., cooling and/or heating) for thermally conductive layer 415 and/or for an electrically active component or other structure thereon, to capture/consume electrical power generated by thermoelectric elements 419′ and 419″, and/or to detect a temperature and/or a temperature gradient between thermally conductive layers 411a/411b and 415. Such an electrical circuit, for example, may include a controller electrically coupled to thermoelectric elements 419′ and 419″, wherein the controller is configured to generate an electrical current through thermoelectric element 419′ and 419″ to provide thermoelectric cooling and/or heating of thermally conductive layer 415 and/or a component thereon. The electrical circuit may include an electrical load configured to receive electrical power from thermoelectric elements 419′ and 419″ responsive to a temperature gradient between thermally conductive layers 411a/411b and 415. The electrical circuit, for example, may include a device to be charged or powered such as a battery, a capacitor, a charging circuit, a power converter, or other load. The electrical circuit may include a controller configured to detect a temperature of thermally conductive layer 415 and/or to detect a temperature gradient between thermally conductive layers 411a/411b and 415 responsive an electrical characteristic of thermoelectric elements 419′ and 419″ (such as a current/voltage generated by and/or an electrical resistance of the thermoelectric elements).

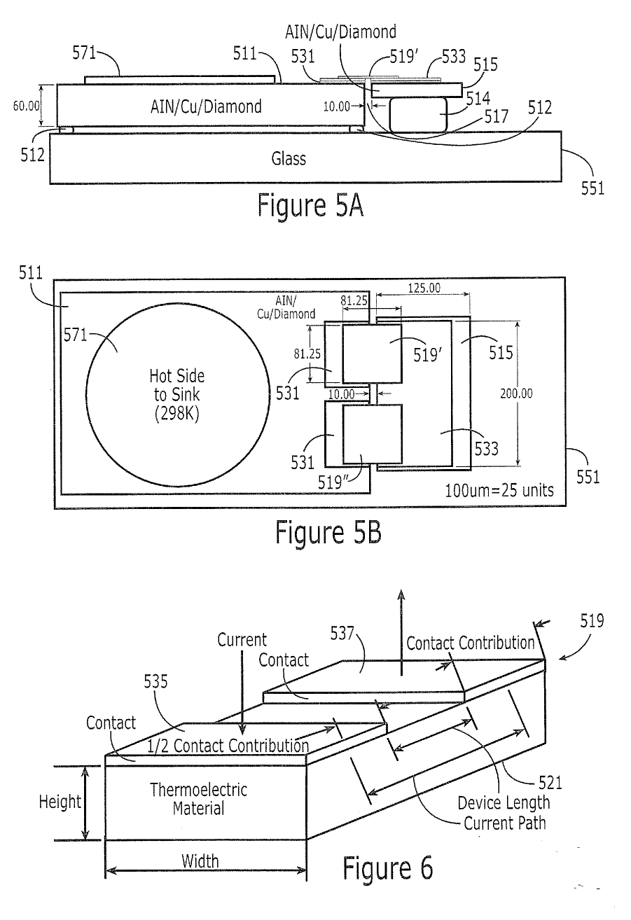

FIGS. 5A and 5A are respective cross sectional and plan views of a thermoelectric structure including bridging thermoelectric elements 519′ and 519″ of opposite conductivity types on a same side of a thermally conductive layer 515 according to some embodiments of the present invention. As shown in FIG. 5, bridging thermoelectric elements 519′ and 519″ may have opposite conductivity types (e.g., n-type and p-type, respectively) and the bridging thermoelectric elements 519′ and 519″ may be electrically coupled in series through electrically conductive traces 531 and 533 so that a same electrical current through the bridging thermoelectric elements 519′ and 519″ results in a transfer of heat away from thermally conductive layer 515 to thermally conductive layer 511. In addition, gap 517 may provide thermal isolation between thermally conductive layers 515 and 511.

As shown in FIG. 5, thermally conductive layer 511 may be provided on thermally insulating bonding layers 512 to provide thermal isolation between thermally conductive layer 511 and substrate 551 and to provide bonding therebetween. The substrate 551, for example, may be a glass substrate. Moreover, thermally conductive layer 515 may be provided on a thermally insulating bonding layer 514 to provide thermal isolation between thermally conductive layer 515 and substrate 551. Moreover, thermally conductive layer 511 may be thermally coupled to a heat sink or other structure providing a thermal ground or otherwise capable of dissipating/sourcing heat through thermal interface material 571. Each of the thermally conductive layers 511 and 515 may include a layer of a thermally conductive material such as passivated copper (Cu), gold (Au) coated aluminum nitride (AlN), diamond, silicon, etc.

Each of the thermally conductive layers 511 and 515 may be electrically insulating or may include an electrically insulating layer thereon, and conductive traces 531 and 533 may be provided as patterned metal traces thereon. An electrical current through serially coupled bridging thermoelectric elements 519′ and 519″ as shown in FIG. 5 may thus pump heat from thermally conductive layer 515 to thermally conductive layer 511. While not separately shown in FIG. 5, an electrically active component (e.g., an optical component, an integrated circuit electronic device, a power electronic device, a sensor, etc.) or other structure may be provided on and/or coupled to thermally conductive layer 515 to provide cooling/heating thereof, and/or thermally conductive layer 515 may be/include a substrate (e.g., a semiconductor substrate) of such an electrically active component or other structure.

As shown in FIG. 6, each of the bridging thermoelectric elements 519′/519″ (referred to generically in FIG. 6 as bridging thermoelectric element 519) may include a continuous segment 521 of thermoelectric material bridging gap 517 and respective contact layers 535 and 537 (e.g., including solder) providing electrical and mechanical coupling/contact between the thermoelectric material and electrically conductive traces 531 and 533. Structures including continuous segments of thermoelectric material are discussed above with respect to FIG. 1A. According to other embodiments of the present invention, each of the bridging thermoelectric elements 519′/519″ may include separate segments of thermoelectric material on opposite sides of gap 517 (or a single segment of thermoelectric material on only one side) with a conductive layer (e.g., a metal layer) providing electrical connection across the gaps 517 as discussed above with respect to FIG. 1B. While only two bridging thermoelectric elements 519′ and 519″ are shown by way of example, any number of thermoelectric elements may be provided with platform structures such as that illustrated in FIGS. 5A and 5B.

As shown in FIGS. 5A, 5B, and 6, the continuous segments 521 of thermoelectric material for bridging thermoelectric elements 519′ and 519″ may provide electrical current paths through the thermoelectric material that are substantially parallel with respect to surfaces of thermally conductive layers 511 and 515. Moreover, contact layers 531 and 533 for each of the bridging thermoelectric elements 519′ and 519″ may provide relatively large area metal contacts between continuous segments 521 of thermoelectric material and respective electrically conductive traces 531 and 533.

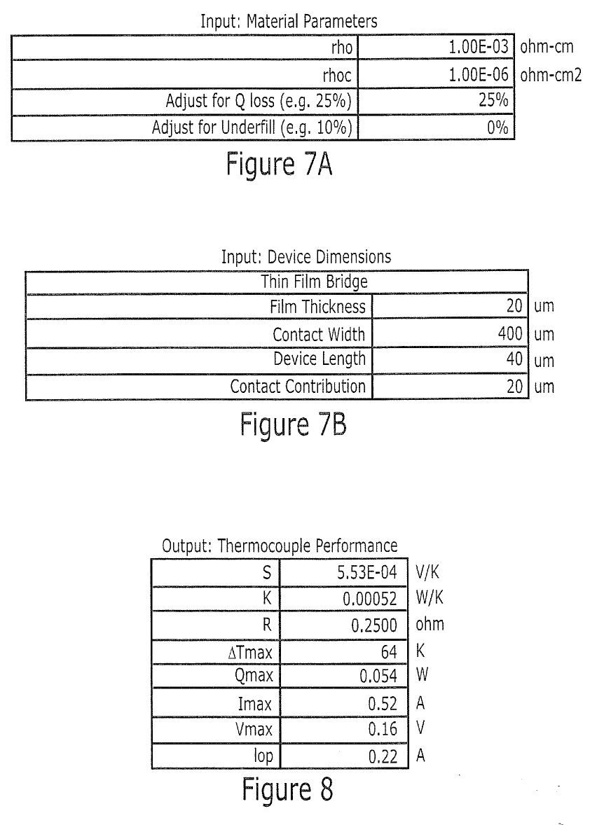

The structure of FIGS. 5A, 5B, and 6 may be used to model behavior of a thermoelectric structure including bridging thermoelectric elements according to some embodiments of the present invention. In FIGS. 5A and 5B, units used to define dimensions of structures may be scaled such that every 25 units illustrated is equal to 100 μm (micrometers). For purposes of modeling, material and contact resistances may be determined based on material and contact dimensions as shown in FIG. 6, and based on thin film thermoelectric cooling models. As shown in FIG. 7A, for example, a resistivity of the thermoelectric material of the continuous segments 521 of thermoelectric material for both of the thermoelectric elements 519′ and 519″ may be 1×10⁻³ Ω-cm (ohm-cm); contact resistance between thermoelectric material of thermoelectric elements 519′ and 519″ may be 1×10⁻⁶ Ω-cm² (ohm-cm²); an adjustment for Q loss (i.e., efficiency) has been assumed to be 25%; and an adjustment for underfill may be 10%. As further shown in FIG. 7B, thermoelectric elements 519 from FIG. 6 may have a thickness (or height) of 201 m (micrometers), a width of 400 μm (micrometers), a length (between contacts 535 and 537) of 401 m (micrometers), and a contact contribution of 20 μm (micrometers).

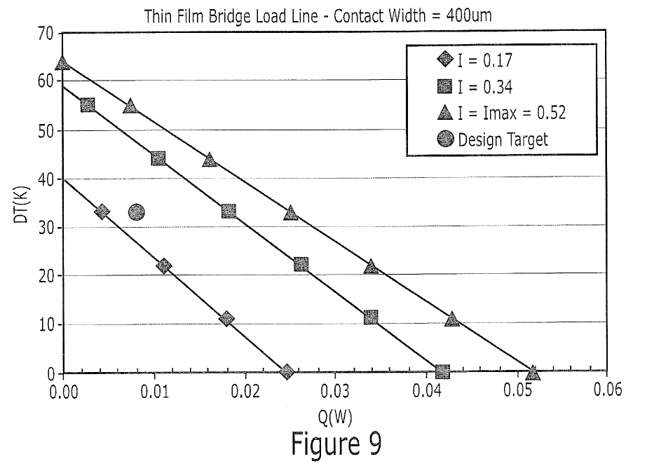

Based on the parameters and dimensions of FIGS. 7A and 7B, the single p-n couple of FIGS. 5A and 5B (including n-type and p-type thermoelectric elements 519′ and 519″) may provide performance characteristics as shown in FIG. 8. More particularly, the modeled p-n couple of FIGS. 5A, 5B, and 6 may provide a Seebeck coefficient (S) of 5.53×10⁻⁴ V/K, a heat conductance (K) of 0.00052 W/K, a resistance (R) of 0.25 Ω(ohm), a maximum temperature gradient (ΔTmax) of 64 K, a maximum heat load (Qmax) of 0.054 W, a maximum current (Imax) of 0.52 A, a maximum voltage (Vmax) of 0.16 V, and an operating current (Iop) of 0.22 A. Load lines at different currents for the modeled structure are illustrated in FIG. 9.

As discussed above with respect to FIGS. 1A, 1B, and 2, an electrical circuit may be configured to provide temperature control (e.g., cooling and/or heating) for thermally conductive layer 515 and/or for an electrically active component or other structure thereon, to capture/consume electrical power generated by thermoelectric elements 519′ and 519″, and/or to detect a temperature and/or a temperature gradient between thermally conductive layers 511 and 515. Such an electrical circuit, for example, may include a controller electrically coupled to thermoelectric elements 519′ and 519″ through electrically conductive traces 531, wherein the controller is configured to generate an electrical current through thermoelectric elements 519′ and 519″ to provide thermoelectric cooling and/or heating of thermally conductive layer 515 and/or a component thereon. The electrical circuit may include an electrical load configured to receive electrical power from thermoelectric elements 519′ and 519″ responsive to a temperature gradient between thermally conductive layers 511 and 515. The electrical circuit, for example, may include a device to be charged or powered such as a battery, a capacitor, a charging circuit, a power converter, or other load. The electrical circuit may include a controller configured to detect a temperature of thermally conductive layer 515 and/or to detect a temperature gradient between thermally conductive layers 511 and 515 responsive an electrical characteristic of thermoelectric elements 519′ and 519″ (such as a current/voltage generated by and/or an electrical resistance of the thermoelectric elements).

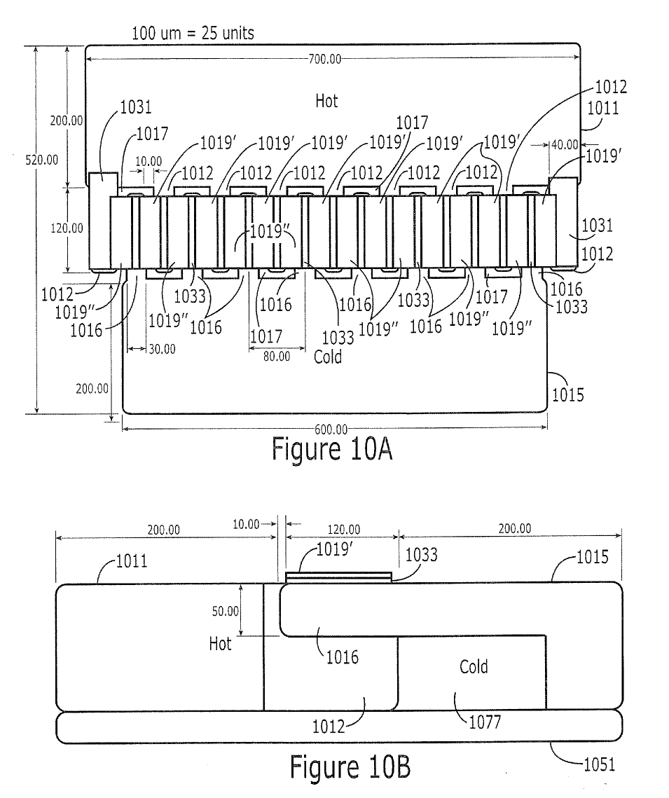

FIG. 10A is a plan view of a thermoelectric structure including bridging thermoelectric elements 1019′ and 1019″ of opposite conductivity types on interdigitated fingers 1012 and 1016 of thermally conductive layers 1011 and 1015. FIG. 10B is an enlarged cross sectional view illustrating a finger 1016 of thermally conductive layer 1015 of FIG. 10A. In the cross sectional view of FIG. 10B, the finger 1016 is in the foreground, and the finger 1012 is in the background behind finger 1016.

As shown in FIGS. 10A and 10B, bridging thermoelectric elements 1019′ and 1019″ may have opposite conductivity types (e.g., n-type and p-type, respectively) and the bridging thermoelectric elements 1019′ and 1019″ may be electrically coupled in series so that a same electrical current through the bridging thermoelectric elements 1019′ and 1019″ results in a transfer of heat away from thermally conductive layer 1015 to thermally conductive layer 1011. More particularly, heat may be transferred from fingers 1016 of thermally conductive layer 1015 through thermoelectric elements 1019′ and 1019″ to fingers 1012 of thermally conductive layer 1011. In addition, gaps 1017 may provide thermal isolation between fingers 1016 of thermally conductive layer 1015 and fingers 1012 of thermally conductive layers 1011, and cavity 1077 may provide thermal isolation between thermally conductive layer 1015 and substrate 1051.

Thermally conductive layer 1011 may be provided on substrate 1051, and the substrate 1051 may comprise a thermally insulating material. Moreover, portions of substrate 1051 between thermally conductive layers 1011 and 1015 may be patterned to increase a thermal resistance thereof. For example, portions of substrate 1051 between thermally conductive layers 1011 and 1015 may be thinned, patterned to provide a serpentine thermal path, etc. Moreover, thermally conductive layer 1011 may be thermally coupled to a heat sink or other structure providing a thermal ground or otherwise capable of dissipating/sourcing heat. Each of the thermally conductive layers 1011 and 1015 may include a layer of a thermally conductive material such as passivated copper (Cu), gold (Au) coated aluminum nitride (AlN), diamond, silicon, etc. Cavity 1077 and/or gaps 1017 may be filled with a gas (e.g., air), a vacuum, and/or a thermally insulating material.

An electrical current through serially coupled bridging thermoelectric elements 1019′ and 1019″ as shown in FIGS. 10A and 10B may thus pump heat from thermally conductive layer 1015 to thermally conductive layer 1011 and/or from thermally conductive layer 1011 to thermally conductive layer 1015. According to some embodiments of the present invention, one or more of thermally conductive layers 1011 and/or 1015 may be electrically insulating and/or may have an electrically insulating layer thereon so that patterned metal traces 1031 and 1033 may provide electrical coupling between bridging thermoelectric elements 1019′ and 1019″.

While not separately shown in FIGS. 10A and 10B, an electrically active component (e.g., an optical component, an integrated circuit electronic device, a power electronic device, a sensor, etc.) or other structure may be provided on and/or coupled to thermally conductive layer 1015 to provide cooling/heating thereof, and/or thermally conductive layer 1015 may be/include a substrate (e.g., a semiconductor substrate) of such an electrically active component or other structure.

Each of the bridging thermoelectric elements 1019′/1019″ may include a continuous segment of thermoelectric material bridging gaps 1017 and respective solder layers as discussed above with respect to FIG. 1A. According to other embodiments of the present invention, each of the bridging thermoelectric elements 1019′/1019″ may include separate segments of thermoelectric material on opposite sides of gap(s) 1017 (or a single segment of thermoelectric material on only one side) with a conductive layer providing electrical connection across the gaps 1017 as discussed above with respect to FIG. 1B. While 16 bridging thermoelectric elements 1019′ and 1019″ (providing eight thermoelectric couples) are shown by way of example, any number of thermoelectric elements may be provided with interdigitated finger structures such as that illustrated in FIGS. 10A and 10B.

As discussed above with respect to FIGS. 1A, 1B, and 2, an electrical circuit may be configured to provide temperature control (e.g., cooling and/or heating) for thermally conductive layer 1015 and/or for an electrically active component or other structure thereon, to capture/consume electrical power generated by thermoelectric elements 1019′ and 1019″, and/or to detect a temperature and/or a temperature gradient between thermally conductive layers 1011 and 1015. Such an electrical circuit, for example, may include a controller electrically coupled to thermoelectric elements electrically conductive traces 1031 at opposite ends of the serially coupled array of thermoelectric elements 1019′ and 1019″, and the controller may be configured to generate an electrical current through thermoelectric elements 1019′ and 1019″ to provide thermoelectric cooling and/or heating of thermally conductive layer 1015 and/or a component thereon. The electrical circuit may include an electrical load configured to receive electrical power from thermoelectric elements 1019′ and 1019″ responsive to a temperature gradient between thermally conductive layers 1011 and 1015. The electrical circuit, for example, may include a device to be charged or powered such as a battery, a capacitor, a charging circuit, a power converter, or other load. The electrical circuit may include a controller configured to detect a temperature of thermally conductive layer 1015 and/or to detect a temperature gradient between thermally conductive layers 1011 and 1015 responsive to an electrical characteristic of thermoelectric elements 1019′ and 1019″ (such as a current/voltage generated by and/or an electrical resistance of the thermoelectric elements).

As shown in FIGS. 10A and 10B, a linear array of serially connected thermoelectric elements 1019′ and 1019″ may be provided on interdigitated finger structures. According to other embodiments of the present invention, an array of thermoelectric elements may be provided on interdigitated finger structures surrounding a thermally conductive layer.

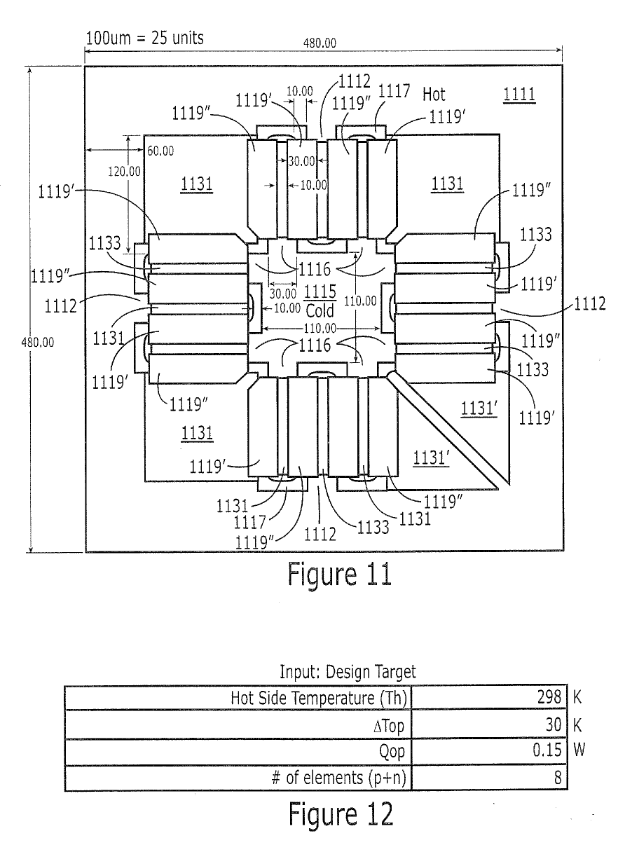

FIG. 11 is a plan view of a thermoelectric structure including bridging thermoelectric elements 1119′ and 1119″ of opposite conductivity types on interdigitated fingers 1112 and 1116 of thermally conductive layers 1111 and 1115. As shown in FIG. 11, bridging thermoelectric elements 1119′ and 1119″ may have opposite conductivity types (e.g., n-type and p-type, respectively) and the bridging thermoelectric elements 1119′ and 1119″ may be electrically coupled in series so that a same electrical current through the bridging thermoelectric elements 1019′ and 1019″ results in a transfer of heat away from thermally conductive layer 1115 to thermally conductive layer 1111. By reversing the electrical current, heat may be transferred from thermally conductive layer 1111 to thermally conductive layer 1115. More particularly, heat may be transferred from fingers 1116 of thermally conductive layer 1115 through thermoelectric elements 1119′ and 1119″ to fingers 1112 of thermally conductive layer 1111. In addition, gaps 1117 may provide thermal isolation between fingers 1116 of thermally conductive layer 1115 and fingers 1112 of thermally conductive layer 1111. While not explicitly shown in FIG. 11, a cavity may provide thermal isolation between thermally conductive layer 1115 and a supporting substrate as discussed above with respect to FIG. 10B.

As shown in FIG. 11, thermally conductive layer 1115 may have a square shape with two fingers 1116 extending from each side thereof. While two fingers per side are shown by way of example, any number of fingers and corresponding thermoelectric elements may be provided. Moreover, the thermally conductive layer 1111 may surround the thermally conductive layer 1115 so that heat may be pumped to/from all sides thereof.

Thermally conductive layers 1111 and 1115 may be provided on a thermally insulating substrate (not shown) with both of the thermally conductive layers 1111 and 1115 being directly coupled to the substrate. According to other embodiments of the present invention, bridging thermoelectric elements 1119′ and 1119″ may provide mechanical support for thermally conductive layer 1115 so that thermally conductive layer 1115 and fingers 1133 are suspended by bridging thermoelectric elements 1119′ and 1119″ (without direct support from an underlying substrate). According to still other embodiments of the present invention, thin thermally insulating layers (e.g., layers of silicon oxide, silicon nitride, magnesium oxide, polyimide, etc.) may extend laterally from thermally conductive layer 1111 and/or fingers 1112 to thermally conductive layer 1115 and/or fingers 1116 to support thermally conductive layer 1115 (without direct support from an underlying substrate).

Thermally conductive layer 1111 may be thermally coupled to a heat sink or other structure providing a thermal ground or otherwise capable of dissipating/sourcing heat. Moreover, each of the thermally conductive layers 1111 and 1115 may include a layer of a thermally conductive material such as passivated copper (Cu), gold (Au) coated aluminum nitride (AlN), diamond, silicon, etc. Gaps 1117 may be filled with a gas (e.g., air), a vacuum, and/or a thermally insulating material.

An electrical current through serially coupled bridging thermoelectric elements 1119′ and 1119″ as shown in FIG. 11 may thus pump heat from thermally conductive layer 1115 to thermally conductive layer 1111. According to some embodiments of the present invention, one or more of thermally conductive layers 1111 and/or 1115 may be electrically insulating and/or may have an electrically insulating layer thereon so that patterned metal traces 1131 and 1133 may provide electrical coupling between bridging thermoelectric elements 1119′ and 1119″.

While not separately shown in FIG. 11, an electrically active component (e.g., an optical component, an integrated circuit electronic device, a power electronic device, a sensor, etc.) or other structure may be provided on and/or coupled to thermally conductive layer 1115 to provide cooling/heating thereof, and/or thermally conductive layer 1115 may be/include a substrate (e.g., a semiconductor substrate) of such an electrically active component or other structure. For example, thermally conductive layer 1115 may be a semiconductor substrate of an electrically active component.

Each of the bridging thermoelectric elements 1119′/1119″ may include a continuous segment of thermoelectric material bridging gaps 1117 and respective solder layers as discussed above with respect to FIG. 1A. According to other embodiments of the present invention, each of the bridging thermoelectric elements 1119′/1119″ may include separate segments of thermoelectric material on opposite sides of gap(s) 1117 (or a single segment of thermoelectric material on only one side) with a conductive layer providing electrical connection across the gaps 1117 as discussed above with respect to FIG. 1B. While 16 bridging thermoelectric elements 1119′ and 1119″ are shown by way of example, any number of thermoelectric elements may be provided with interdigitated finger structures such as that illustrated in FIG. 11.

As discussed above with respect to FIGS. 1A, 1B, and 2, an electrical circuit may be configured to provide temperature control (e.g., cooling and/or heating) for thermally conductive layer 1115 and/or for an electrically active component or other structure thereon, to capture/consume electrical power generated by thermoelectric elements 1119′ and 1119″, and/or to detect a temperature and/or a temperature gradient between thermally conductive layers 1111 and 1115. Such an electrical circuit, for example, may include a controller electrically coupled to electrically conductive traces 1131 at opposite ends of the serially coupled array of thermoelectric elements 1119′ and 1119″, and the controller may be configured to generate an electrical current through thermoelectric elements 1119′ and 1119″ to provide thermoelectric cooling and/or heating of thermally conductive layer 1115 and/or a component thereon. The electrical circuit may include an electrical load configured to receive electrical power from thermoelectric elements 1119′ and 1119″ responsive to a temperature gradient between thermally conductive layers 1111 and 1115. The electrical circuit, for example, may include a device to be charged or powered such as a battery, a capacitor, a charging circuit, a power converter, or other load. The electrical circuit may include a controller configured to detect a temperature of thermally conductive layer 1115 and/or to detect a temperature gradient between thermally conductive layers 1111 and 1115 responsive an electrical characteristic of thermoelectric elements 1119′ and 1119″ (such as a current/voltage generated by and/or an electrical resistance of the thermoelectric elements).

As shown in FIG. 11, thermoelectric elements 1119′ and 1119″ may be arranged symmetrically around thermally conductive layer 1115 to provide symmetric cooling of thermally conductive layer 1115. Accordingly, to other embodiments of the present invention, thermoelectric elements may be arranged asymmetrically around thermally conductive layer 1115 to provide asymmetric cooling of thermally conductive layer 1115. For example, more or fewer thermoelectric elements may be arranged on one side of thermally conductive layer than are arranged on another side; one or more sides of thermally conductive layer 1115 may be free of thermoelectric elements; and/or spacings of thermoelectric elements on a same side of thermally conductive layer 1115 may be asymmetric.

The thermoelectric structures of FIGS. 10A and 11 each include 8 p-n thermoelectric couples (with each p-n thermoelectric couple including one p-type thermoelectric element and one n-type thermoelectric element), and these structures may be used to model behavior of thermoelectric structures according to some embodiments of the present invention. In FIGS. 10A and 11, units used to define dimensions of structures may be scaled such that every 25 units illustrated is equal to 100 μm (micrometers). For purposes of modeling, thermoelectric elements 1019′ and 1019″ of FIG. 10A and thermoelectric elements 1119′ and 1119″ of FIG. 11 may have continuous segments of thermoelectric material with dimensions as discussed above with respect to FIGS. 6 and 7B (i.e., 400 μm×20 μm×40 μm) and with material properties as discussed above with respect to FIGS. 7A and 7B.

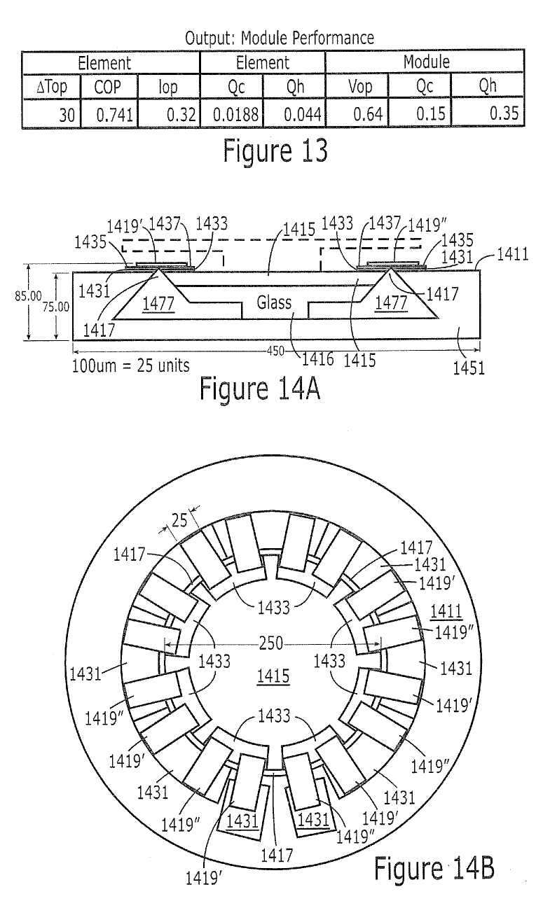

FIGS. 12 and 13 are tables illustrating parameters used to model performance of thermoelectric structures of FIGS. 10A and 11. As discussed with respect to FIGS. 12 and 13, an element refers to a p-n couple including a p-type thermoelectric element and an n-type thermoelectric element so that structures of FIGS. 10A and 11 may be defined to include 8 elements. More particularly, a hot side temperature (Th) may be 298 K at thermally conductive layer 1011/1111, an operating temperature difference (ΔTop) may be 30 K between cold side thermally conductive layer 1015/1115 and hot side thermally conductive layer 1011/1111, an operating power (Qop) may be 0.15 W, an operating current (Iop) may be 0.32 V, and an operating voltage (Vop) may be 0.64 V across the 8 thermoelectric p-n couples. For each thermoelectric p-n couple, 0.0188 W of heat being transferred from the cold (cooled) side (Qc) may be achieved with 0.044 W of heat being transferred to the hot side (Qh). For the complete module (including 8 p-n couples), about 0.15 W of heat transfer from the cold (cooled) side (Qc) may be achieved with about 0.35 W of heat being transferred to the hot side (Qh) and a coefficient of performance (COP) of about 0.741.

In the thermoelectric structure of FIG. 10A with thermally conductive layer 1015 providing a cold stage area of about 0.024 cm², a heat flux of up to about 18 W/cm² may be pumped. In the thermoelectric structure of FIG. 11 with thermally conductive layer 1115 providing a cold stage area of about 0.0065 cm², a heat flux of up to about 66 W/cm² may be pumped.

FIGS. 14A and 14B are respective cross-sectional and plan views of a thermoelectric structure including bridging thermoelectric elements 1419′ and 1419″ of opposite conductivity types around a circular thermally conductive layer 1415 according to some embodiments of the present invention. Bridging thermoelectric elements 1419′ and 1419″ may have opposite conductivity types (e.g., n-type and p-type, respectively) and the bridging thermoelectric elements 1419′ and 1419″ may be electrically coupled in series so that a same electrical current through the bridging thermoelectric elements 1419′ and 1419″ results in a transfer of heat away from thermally conductive layer 1415 to thermally conductive layer 1411. By reversing the electrical current, heat may be transferred from thermally conductive layer 1411 to thermally conductive layer 1415. Moreover, thermally conductive layer 1411 may surround thermally conductive layer 1415. In addition, gap 1417 may provide thermal isolation between thermally conductive layers 1415 and 1411, and cavity 1477 may provide electrical isolation between thermally conductive layer 1415 and substrate 1451.

As shown in FIG. 14A, thermally conductive layer 1411 and substrate 1451 may comprise a same material. More particularly, thermally conductive layer 1411 and substrate may be fabricated from a solid substrate, for example, using microfabrication techniques. According to other embodiments of the present invention, thermally conductive layer 1411 and substrate 1451 may be formed of different materials. Moreover, thermally conductive layer 1411 may be thermally coupled to a heat sink or other structure providing a thermal ground or otherwise capable of dissipating/sourcing heat. Each of the thermally conductive layers 1411 and 1415 may include a layer of a thermally conductive material such as passivated copper (Cu), gold (Au) coated aluminum nitride (AlN), diamond, silicon, etc.

As further shown in FIG. 14A, support structure 1416 may support thermally conductive layer 1415 relative to substrate 1451. Portions of support structure 1416 may be relatively narrow (in a lateral dimension parallel with respect to a surface of substrate 451) and/or comprise a thermally insulating material (e.g., silicon oxide, silicon nitride, etc.) to provide thermal isolation between thermally conductive layer 1415 and substrate 1451. By reducing a size of support structure 1416 in a dimension parallel with respect to a surface of substrate 1451, a size of cavity 1477 may be increased thereby increasing thermal isolation. Cavity 1477 and/or gaps 1417 may be filled with a gas (e.g., air), a vacuum, and/or a thermally insulating material. By providing a coupling of support structure 1416 to substrate 1451 at a central portion of thermally conductive layer 1415, a thermal path through support structure 1416 between thermally conductive layer 1415 and thermally conductive layer 1411 may be increased. According to other embodiments of the present invention, support structure 1416 may be omitted so that bridging thermoelectric elements 1419′ and 1419″ provide mechanical support for thermally conductive layer 1415. According to still other embodiments of the present invention, support structure 1416 may be omitted with thin thermally insulating layers (e.g., layers of silicon oxide, silicon nitride, magnesium oxide, polyimide, etc.) extending laterally from layers 1411 to support thermally conductive layer 1415.

An electrical current through serially coupled bridging thermoelectric elements 1419′ and 1419″ as shown in FIGS. 14A and 14B may thus pump heat from thermally conductive layer 1415 to thermally conductive layer 1411. According to some embodiments of the present invention, one or more of thermally conductive layers 1411 and/or 1415 may be electrically insulating and/or may have an electrically insulating layer thereon so that patterned metal traces 1431 and 1433 may provide electrical coupling between bridging thermoelectric elements.

While not separately shown in FIGS. 14A and 14B, an electrically active component (e.g., an optical component, an integrated circuit electronic device, a power electronic device, a sensor etc.) or other structure may be provided on and/or coupled to thermally conductive layer 1415 to provide cooling/heating thereof, and/or thermally conductive layer 1415 may be/include a substrate (e.g., a semiconductor substrate) of such an electrically active component or other structure.

Each of the bridging thermoelectric elements 1419′/1419″ may include a continuous segment of thermoelectric material bridging gap 1417 and respective solder layers 1435 and 1437 as discussed above with respect to FIG. 1A. According to other embodiments of the present invention, each of the bridging thermoelectric elements 1419′/1419″ may include separate segments of thermoelectric material on opposite sides of gap 1417 (or a single segment of thermoelectric material on only one side) with a conductive layer providing electrical connection across the gap 1417 as discussed above with respect to FIG. 1B. While only 16 bridging thermoelectric elements 1419′ and 1419″ (providing 8 p-n couples) are shown by way of example, any number of thermoelectric elements/couples may be provided with platform structures such as that illustrated in FIGS. 14A and 14B.

As discussed above with respect to FIGS. 1A, 1B, and 2, an electrical circuit may be configured to provide temperature control (e.g., cooling and/or heating) for thermally conductive layer 1415 and/or for an electrically active component or other structure thereon, to capture/consume electrical power generated by thermoelectric elements 1419′ and 1419″, and/or to detect a temperature and/or a temperature gradient between thermally conductive layers 1411 and 1415. Such an electrical circuit, for example, may include a controller electrically coupled to thermoelectric elements 1419′ and 1419″, wherein the controller is configured to generate an electrical current through thermoelectric element 1419′ and 1419″ to provide thermoelectric cooling and/or heating of thermally conductive layer 1415 and/or a component thereon. The electrical circuit may include an electrical load configured to receive electrical power from thermoelectric elements 1419′ and 1419″ responsive to a temperature gradient between thermally conductive layers 1411 and 1415. The electrical circuit, for example, may include a device to be charged or powered such as a battery, a capacitor, a charging circuit, a power converter, or other load. The electrical circuit may include a controller configured to detect a temperature of thermally conductive layer 1415 and/or to detect a temperature gradient between thermally conductive layers 1411 and 1415 responsive an electrical characteristic of thermoelectric elements 1419′ and 1419″ (such as a current/voltage generated by and/or an electrical resistance of the thermoelectric elements).

According to some embodiments of the present invention, each of the thermoelectric elements 1419′ and 1419″ may have a width of 100 μm (micrometers) and a thickness (or height) of 20 μm (micrometers). Moreover, thermally conductive layer 1415 may define a circular platform having a diameter of about 1 mm, and thermally conductive layer 1411 may define a surrounding platform having an outer diameter of about 1.8 mm. In addition, a secondary cooled platform may be provided on thermally conductive layer 1415 as indicated by the dotted lines of FIG. 14A. A secondary cooled platform may be provided to match a geometry and/or power pumping of a particular application and/or to physically protect thermoelectric elements 1419′ and 1419″.

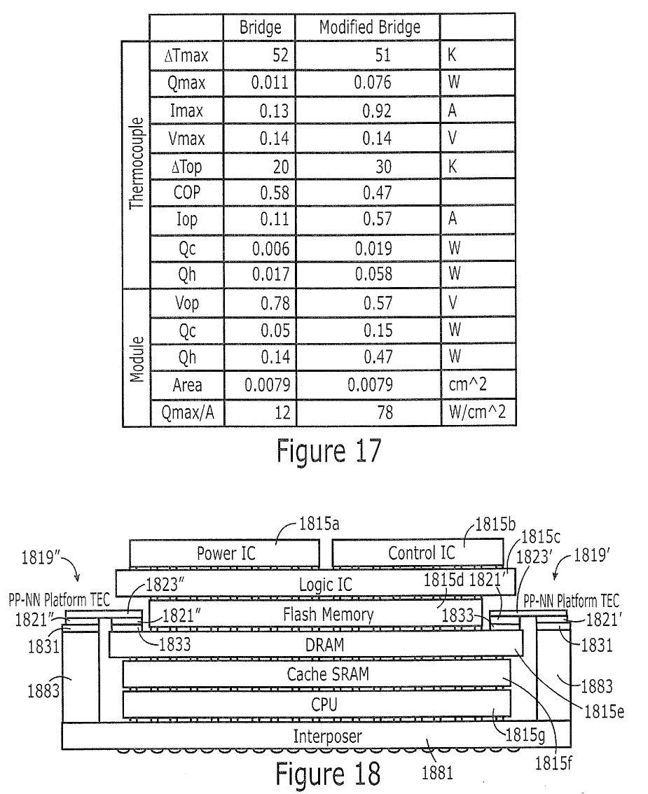

FIG. 17 is a table illustrating performance characteristics of a thermoelectric cooler having a structure as illustrated in FIGS. 14A and 14B. In particular, the column labeled “Bridge” provides performance characteristics for the structure of FIGS. 14A and 14B including thermoelectric elements 1419′ and 1419″ having the structure discussed above with respect to FIG. 1A. The column labeled “Modified Bridge” provides performance characteristics for the structure of FIGS. 14A and 14B including thermoelectric elements 1419′ and 1419″ having the structure (i.e., thermoelectric element 119b) discussed above with respect to FIG. 1B. More particularly, the modeled data of FIG. 17 may be provided for the structure of FIGS. 14A and 14B with the following dimensions: each of the thermoelectric elements 1419′ and 14119″ may have a width of 100 μm (micrometers) and a thickness (or height) of 20 μm (micrometers); thermally conductive layer 1415 may define a circular platform having a diameter of about 1 mm; and thermally conductive layer 1411 may define a surrounding platform having an outer diameter of about 1.8 mm.

In the table of FIG. 17, ΔTmax is a maximum temperature gradient for a thermoelectric couple (including a p-type thermoelectric element and an n-type thermoelectric element), Qmax is a maximum heat transfer for the thermoelectric couple, Imax is the current at ΔTmax for the thermoelectric couple, Vmax is a voltage at Imax of the thermoelectric couple, ΔTop is an operating temperature gradient (between thermally conductive layers 1411 and 1415), COP is a coefficient of performance for the thermoelectric couple, lop is an operating current, Qc (Thermocouple) is heat transfer from the cold (cooled) side (at operating temperature gradient ΔTop and operating current Iop) for the thermoelectric couple, and Qh (Thermocouple) heat transfer to the hot side (at operating temperature gradient ΔTop and operating current lop) for the thermoelectric couple. Moreover, Vop (Module) is an operating voltage across the eight serially coupled thermoelectric couples of FIGS. 14A and 14B (including 16 thermoelectric elements 1419′ and 1419″), Qc (Module) is heat transfer from the cold (cooled) side for the eight serially coupled thermoelectric couples, Qh (Module) is heat transfer to the hot side (at operating temperature gradient ΔTop and operating current lop) for the eight serially coupled thermoelectric couples, Area is an area of thermally conductive layer 1415, and Qmax/A is a measure of heat transfer per unit area.

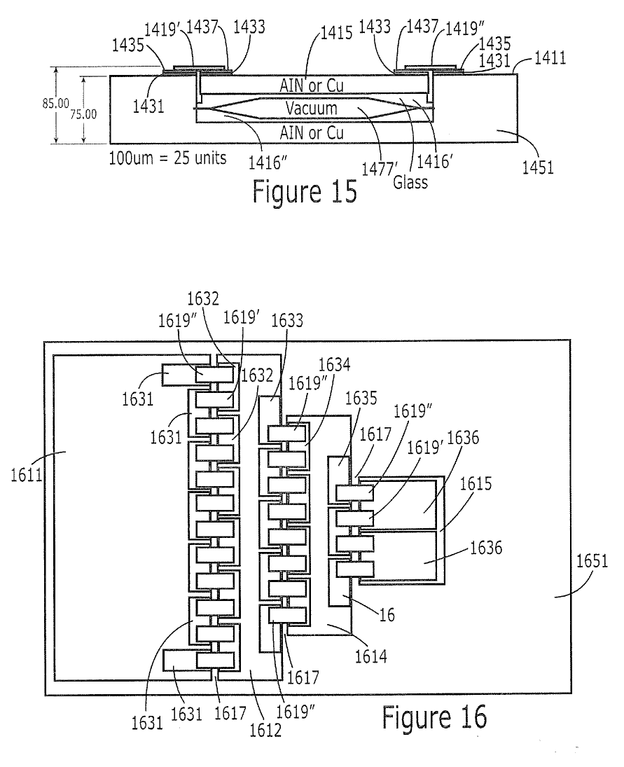

FIG. 15 is a cross sectional view illustrating an alternative cavity/support structure 1477′/1416′/1416″ that may be provided instead of the cavity/support structure 1477/1416 discussed above with respect to FIGS. 14A and 14B. All other elements of FIG. 15 are the same as those discussed above with respect to FIGS. 14A and 14B. In FIG. 15, layers 1416′ and 1416″ of a thermally insulating material may support thermally conductive layer 1415 while defining a sealed cavity 1477′. Accordingly, the sealed cavity 1477′ may be used to maintain a vacuum thereby improving thermal insulation/isolation between thermally conductive layer 1415 and substrate 1451.

FIG. 16 is a plan view of a staged thermoelectric structure including bridging thermoelectric elements 1619′ and 1619″ of opposite conductivity types bridging staged thermally conductive layers 1611/1612/1614/1615 according to some embodiments of the present invention. The structure of FIG. 16 may be similar to that of FIGS. 5A and 5B with two intermediate staged thermally conductive layers and with additional thermoelectric elements bridging between each of the stages. Moreover, thermally conductive layers 1612, 1614, and 1615 may be thermally isolated from substrate 1651, from each other, and/or from thermally conductive layer 1611. The structure of FIG. 16 may thus provide a linear cascade of thermally conductive layers to increase a temperature delta that may be provided between thermally conductive layers 1611 and 1615.

As shown in FIG. 16, bridging thermoelectric elements 1619′ and 1619″ may have opposite conductivity types (e.g., n-type and p-type, respectively) and the bridging thermoelectric elements 1619′ and 1619″ may be electrically coupled in series through electrically conductive traces 1631, 1632, 1633, 1634, 1635, and 1636. As shown in FIG. 16, bridging thermoelectric elements 1619′ and 1619″ between two thermally conductive layers or stages may be electrically connected in series so that a same electrical current through the bridging thermoelectric elements 1619′ and 1619″ between two stages results in a transfer of heat from one of the thermally conductive layers to the other. In addition, gaps 1617 may provide thermal isolation between thermally conductive layers 1611 and 1612, between thermally conductive layers 1612 and 1614, and between thermally conductive layers 1614 and 1615.

For example, heat may be pumped from thermally conductive layer 1615 to thermally conductive layer 1614 to thermally conductive layer 1612 to thermally conductive layer 1611 to provide thermoelectric cooling of thermally conductive layer 1615 and/or a component thereon. A greater number of thermoelectric elements 1619′ and 1619″ may be provided at each stage as shown in FIG. 16 to accommodate an increase in thermal energy at each stage resulting from an electrical current used to drive the thermoelectric elements. Moreover, thermoelectric elements at each stage may be electrically coupled in one series circuit so that all of the thermoelectric elements at all stages may be controlled using one pair of terminals. According to other embodiments of the present invention, thermoelectric elements at different stages may be separately controlled by providing different input/output terminals for thermoelectric elements at different stages.

Thermally conductive layer 1611 may be provided on thermally insulating bonding layers to provide thermal isolation between thermally conductive layer 1611 and substrate 1651 and to provide bonding therebetween. The substrate 1651, for example, may be a glass substrate. Moreover, thermally conductive layers 1612, 1614, and 1615 may be provided on respective thermally insulating bonding layers to provide thermal isolation between thermally conductive layer 1612/1614/1615 and substrate 1651. Moreover, thermally conductive layer 1611 may be thermally coupled to a heat sink or other structure providing a thermal ground or otherwise capable of dissipating/sourcing heat. Each of the thermally conductive layers 1611/1612/1614/1615 may include a layer of a thermally conductive material such as passivated copper (Cu), gold (Au) coated aluminum nitride (AlN), diamond, silicon, etc.

Each of the thermally conductive layers 1611/1612/1614/515 may be electrically insulating or may include an electrically insulating layer thereon, and conductive traces 1631/1632/1633/1634/1635/1636 may be provided as patterned metal traces thereon. An electrical current through serially coupled bridging thermoelectric elements 1619′ and 1619″ as shown in FIG. 16 may thus pump heat from thermally conductive layer 1615 to thermally conductive layer 1614 to thermally conductive layer 1612 to thermally conductive layer 1611. While not separately shown in FIG. 16, an electrically active component (e.g., an optical component, an integrated circuit electronic device, a power electronic device, a sensor, etc.) or other structure may be provided on and/or coupled to thermally conductive layer 1615 to provide cooling/heating thereof, and/or thermally conductive layer 1615 may be/include a substrate (e.g., a semiconductor substrate) of such an electrically active component or other structure.

Each of the bridging thermoelectric elements 1619′/1619″ may include a continuous segment of thermoelectric material bridging a respective gap 1617 and respective contact layers (e.g., including solder) providing electrical and mechanical coupling/contact between the thermoelectric material and respective electrically conductive traces 1631/1632/1633/1634/1635/1635. Structures including continuous segments of thermoelectric material are discussed above with respect to FIG. 1A. According to other embodiments of the present invention, each of the bridging thermoelectric elements 1619′/1619″ may include separate segments of thermoelectric material on opposite sides of a respective gap 1617 (or a single segment of thermoelectric material on only one side) with a conductive layer (e.g., a metal layer) providing electrical connection across the gap 1617 as discussed above with respect to FIG. 1B.

As discussed above with respect to FIGS. 1A, 1B, and 2, an electrical circuit may be configured to provide temperature control (e.g., cooling and/or heating) for thermally conductive layer 1615 and/or for an electrically active component or other structure thereon, to capture/consume electrical power generated by thermoelectric elements 1619′ and 1619″, and/or to detect a temperature and/or a temperature gradient between thermally conductive layers 1611 and 1615. Such an electrical circuit, for example, may include a controller electrically coupled to thermoelectric elements 1619′ and 1619″ through electrically conductive traces 1631/1631/1633/1634/1635/1636 wherein the controller is configured to generate an electrical current through thermoelectric elements 1619′ and 1619″ to provide thermoelectric cooling and/or heating of thermally conductive layer 1615 and/or a component thereon. The electrical circuit may include an electrical load configured to receive electrical power from thermoelectric elements 1619′ and 1619″ responsive to a temperature gradient between thermally conductive layers 1611 and 1615. The electrical circuit, for example, may include a device to be charged or powered such as a battery, a capacitor, a charging circuit, a power converter, or other load. The electrical circuit may include a controller configured to detect a temperature of thermally conductive layer 1615 and/or to detect a temperature gradient between thermally conductive layers 1611 and 1615 responsive an electrical characteristic of thermoelectric elements 1619′ and 1619″ (such as a current/voltage generated by and/or an electrical resistance of the thermoelectric elements).

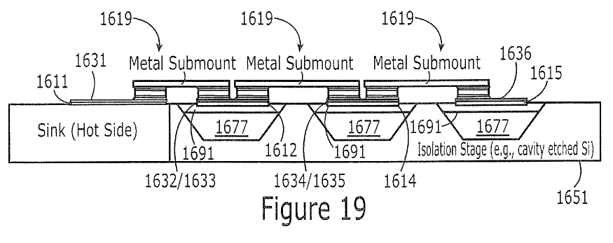

FIG. 19 is a cross sectional view illustrating an implementation of a cascaded thermoelectric structure with thermally conductive layers 1612/1614/1615 supported by relatively thin electrically and thermally insulating layers 1691. The insulating layers 1691, for example, may include layers of silicon oxide, silicon nitride, magnesium oxide, polyimide, etc. Accordingly, cavities 1691 may be provided between thermally conductive layers 1612/1614/1615 and substrate 1651. The thermoelectric structure of FIG. 19 and/or portions thereof may thus be formed using microelectromechanical fabrication techniques, and cavities 1691 may provide thermal isolation for thermally conductive layers 1612/1614/1615.

In the cross sectional view of FIG. 19, electrically conductive traces 1632 and 1633 may be coupled and electrically conductive traces 1634 and 1635 may be coupled to provide an electrical path between thermoelectric elements 1619 of different stages. According to other embodiments of the present invention, thermoelectric elements 1619 of different stages may be electrically isolated as shown in FIG. 16. As shown in FIG. 19, each thermoelectric element 1619 may be provided according to the structure of FIG. 1B (e.g., thermoelectric element 119b). According to other embodiments of the present invention, each thermoelectric element 1619 may be provided according to the structure of FIG. 1A (e.g., thermoelectric element 119a).

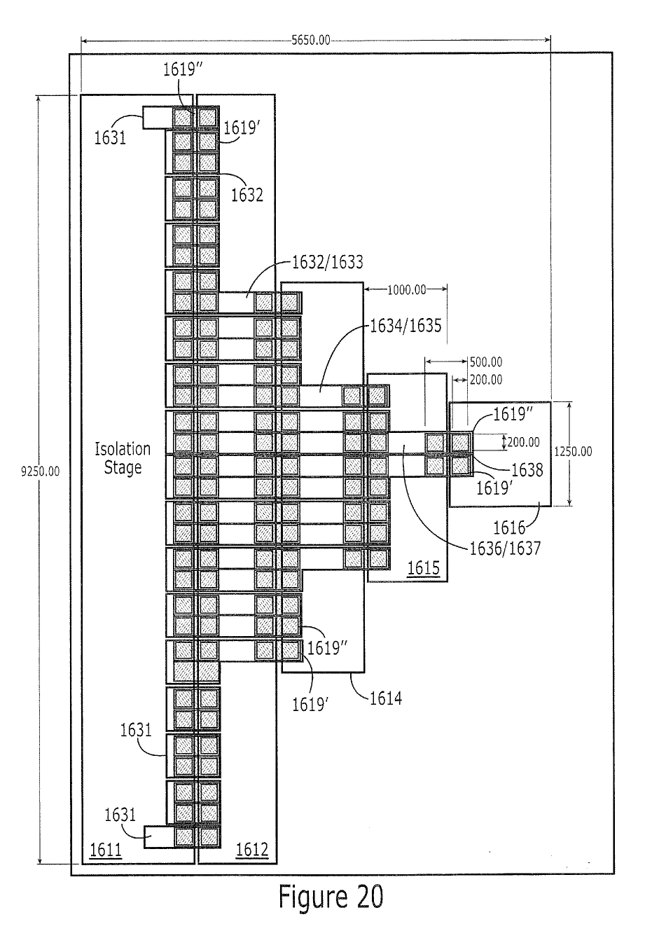

FIG. 20 is a plan view of a cascaded thermoelectric cooling structure including a single current path for thermoelectric elements of all stages according to some embodiments of the present invention. Structures of thermally conductive layers 1611, 1612/1614/1615/1616, substrate 1651, and electrically conductive traces 1631/1632/1633/1634/1635/1636/1637/1638 are the same as discussed above with respect to FIG. 16 (with the addition of fifth thermally conductive layer 1616 and electrically conductive traces 1636/1637/1638). As shown in FIG. 20, some of traces 1632 and 1633 may be coupled, some of traces 1634 and 1635 may be coupled, and some of traces 1636 and 1637 may be coupled. Accordingly, one pair of input/output terminals may be used to control all thermoelectric elements of all stages, and all thermoelectric elements may work at a same current.

FIG. 18 is a cross sectional view of a three dimensional electronic structure including a stack of semiconductor integrated circuit (IC) devices 1815a-g according to still further embodiments of the present invention. For example, one or more of the semiconductor integrated circuit devices 1815a-g of FIG. 18 may include one or more of a power IC device, a control IC device, a logic IC device, a flash memory IC device, a dynamic random access memory (DRAM) IC device, a cache static random access memory (SRAM) IC device, and/or a central processing unit (CPU) IC device. Moreover, the stack of IC devices 1815a-g may be electrically and mechanically coupled to an interposer 1881, for example, using solder interconnections and/or wirebonds, and the interposer 1881 may provide electrical and mechanical interconnection with a next level of packaging (e.g., a printed circuit board), for example, using solder connections.

In addition, a thermally conductive structure 1883 may be provided on the interposer 1881, and thermoelectric elements 1819′ and 1819″ may be provided to pump heat between the stack of integrated circuit devices 1815a-g. Moreover, electrical coupling may be provided between thermoelectric elements 1819′ and 1819″ using an electrically conductive trace across IC device 1815e. As shown in FIG. 18, each of the thermoelectric elements 1819′ and 1819″ may include two segments of thermoelectric material 1821′/1821″ coupled between conductive metal traces 1831/1833 and respective conductive layers 1823′/1823″. According to other embodiments of the present invention, one of the segments of thermoelectric material 1821′/1821″ may be omitted from each of the thermoelectric elements 1819′ and 1819″. Accordingly, the thermoelectric elements 1819′ and 1819″ may have a structure as discussed above with respect to FIG. 1B. According to other embodiments of the present invention, the thermoelectric elements 1819′ and 1819″ may have a structure as discussed above with respect to FIG. 1A.

As shown in FIG. 18, thermoelectric elements 1819′ and 1819″ may be directly thermally coupled to a substrate of IC device 1815e. According to other embodiments of the present invention, thermoelectric elements 1819′ and 1819″ may be coupled to a thermally conductive layer (such as a layer of passivated copper (Cu), gold (Au) coated aluminum nitride (AlN), diamond, silicon, etc.) provided in the stack of IC devices. By way of illustration, IC device 1815e may be replaced with a non-functional thermally conductive layer. Moreover, a controller may be electrically coupled with conductive metal traces 1831 to provide heating/cooling and/or temperature measurement of the stack of IC devices. In addition, thermoelectric heat pumping may be provided at multiple levels of the stack.

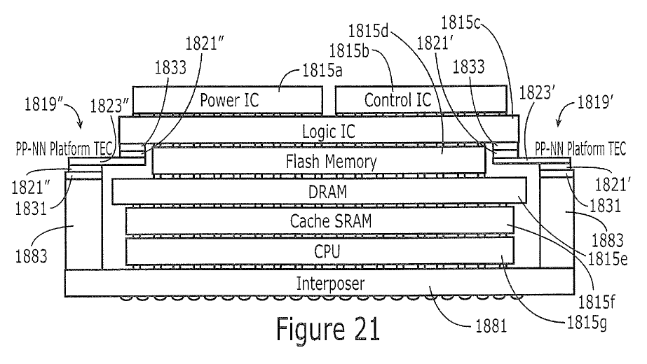

As shown in FIG. 18, thermoelectric elements 1819′ and 1819″ may be thermally coupled to IC device 1815e to provide cooling/heating thereof, and electrically conductive traces on IC device 1815 may provide electrical coupling between the thermoelectric elements. According to other embodiments of the present invention, IC device 1815c may be thermally coupled to thermoelectric elements 1819′ and 1819″ to provide cooling thereof. For example, metal (e.g., solder) couplings may be provided between conductive layers 1823′/1823″ and IC device 1815c while also providing the illustrated thermal and electrical couplings with IC device 1815e. According to still other embodiments of the present invention, thermoelectric elements 1819′ and 1819″ may be electrically, mechanically, and thermally coupled to IC device 1815c without providing coupling to IC device 1815e so that metal traces 1831 and IC device 1815c are coupled to opposite sides of thermoelectric elements 1819′ and 1819″ as shown in FIG. 21. Accordingly, thermoelectric elements 1819′ and 1819″ may be coupled to surfaces of thermally conductive layers (e.g., IC device 1815c and thermally conductive structure) facing in opposite directions.

While the present invention has been particularly shown and described with reference to embodiments thereof, it will be understood by those of ordinary skill in the art that various changes in form and details may be made therein without departing from the spirit and scope of the present invention as defined by the following claims.

That which is claimed is:

1. A thermoelectric structure comprising:
first and second thermally conductive layers wherein the first and second thermally conductive layers are laterally spaced apart in a direction parallel with respect to surfaces of the first and second thermally conductive layers so that a gap is defined between edges of the first and second thermally conductive layers; and
a thermoelectric element bridging the gap between the first and second thermally conductive layers wherein the thermoelectric element includes a thermoelectric material on respective surface portions of at least one of the first and second thermally conductive layers.

2. A thermoelectric structure according to claim 1 wherein the thermoelectric element comprises a continuous segment of the thermoelectric material bridging the gap between the first and second thermally conductive layers.

3. A thermoelectric structure according to claim 1 wherein the thermoelectric element comprises a first segment of thermoelectric material on the first thermally conductive layer, a second segment of thermoelectric material on the second thermally conductive layer, and an electrically conductive layer on the first and second segments of the thermoelectric material, wherein the first and second segments of the thermoelectric material have a same conductivity type, and wherein the first and second segments of the thermoelectric material are separated by the gap.

4. A thermoelectric structure according to claim 1 wherein the thermoelectric element comprises a first thermoelectric element and the thermoelectric material comprises a first thermoelectric material having a first conductivity type, the thermoelectric structure further comprising:
a second thermoelectric element bridging the gap between the first and second thermally conductive layers wherein the second thermoelectric element includes a second thermoelectric material having a second conductivity type on second surface portions of at least one of the first and second thermally conductive layers, wherein the first and second conductivity types are different.

5. A thermoelectric structure according to claim 4 wherein the first and second thermoelectric elements are electrically coupled in series so that current flows through the first thermoelectric element in a direction from the first thermally conductive layer toward the second thermally conductive layer while current flows through the second thermoelectric element in a direction from the second thermally conductive layer toward the first thermally conductive layer.

6. A thermoelectric structure according to claim 4 wherein the first thermally conductive layer defines a recess and the second thermally conductive layer defines an extension extending into the recess so that the gap extends around the extension between the extension and the recess, and wherein the first and second thermoelectric elements bridge the gap between the first and second thermally conductive layers on opposite sides of the extension.

7. A thermoelectric structure according to claim 1 wherein the first and second thermally conductive layers are thermally isolated.

8. A thermoelectric structure according to claim 1 wherein surfaces of the first and second thermally conductive layers are substantially coplanar.

9. A thermoelectric structure according to claim 1 wherein the second thermally conductive layer surrounds the first thermally conductive layer.

10. A thermoelectric structure according to claim 9 wherein the thermoelectric element comprises a first thermoelectric element, the thermoelectric structure further comprising:
a second thermoelectric element bridging the gap between the first and second thermally conductive layers, wherein the first and second thermoelectric elements are on opposites sides of the first thermally conductive layer.

11. A thermoelectric structure according to claim 1 wherein the gap between the first and second thermally conductive layers is free of the thermoelectric material.

12. A thermoelectric structure according to claim 1 wherein the first and second thermally conductive layers are supported on a same substrate and wherein a cavity is defined between portions of the first thermally conductive layer and the substrate.

13. A thermoelectric structure according to claim 12 further comprising:
a thermally insulating layer providing mechanical coupling between the first thermally conductive layer and the substrate wherein the cavity is further defined between portions of the thermally insulating layer and the substrate.

14. A thermoelectric structure according to claim 13 wherein the thermally insulating layer comprises a layer of a thermally insulating material including silicon oxide, silicon nitride, magnesium oxide, and/or polyimide.

15. A thermoelectric structure according to claim 1 further comprising:
an electrically active component on the first thermally conductive layer so that the electrically active component and the thermoelectric element are on a same surface of the first thermally conductive layer.

16. A thermoelectric structure according to claim 1 wherein the gap comprises a first gap and wherein the thermoelectric element comprises a first thermoelectric element, the thermoelectric structure further comprising:
a third thermally conductive layer laterally spaced apart from the second thermally conductive layer in the direction parallel with respect to surfaces of the first, second, and third thermally conductive layers so that the second thermally conductive layer is between the first and third thermally conductive layers and so that a second gap is defined between edges of the second and third thermally conductive layers; and
a second thermoelectric element bridging the gap between the second and third thermally conductive layers wherein the second thermoelectric element includes a thermoelectric material on respective surface portions of at least one of the second and third thermally conductive layers.

17. A thermoelectric structure according to claim 1 wherein the first thermally conductive layer comprises a semiconductor substrate.

18. A thermoelectric structure according to claim 1 further comprising:
first and second electronic substrates mechanically coupled to opposite sides of the first thermally conductive layer.

19. A thermoelectric structure according to claim 1 further comprising:
a controller electrically coupled to the thermoelectric element wherein the controller is configured to generate an electrical current through the thermoelectric element to provide thermoelectric cooling and/or heating of the first thermally conductive layer.

20. A thermoelectric structure according to claim 1 further comprising:
an electrical load coupled to the thermoelectric element configured to receive electrical power from the thermoelectric element responsive to a temperature gradient between the first and second thermally conductive layers.

21. A thermoelectric structure according to claim 1 further comprising:
a controller electrically coupled to the thermoelectric element wherein the controller is configured to detect a temperature of the first thermally conductive layer and/or to detect a temperature gradient between the first and second thermally conductive layers responsive an electrical characteristic of the thermoelectric element.

22. A thermoelectric structure according to claim 1 wherein the thermoelectric element comprises a segment of thermoelectric material on the first thermally conductive layer and an electrically conductive layer on the segment of the thermoelectric material, wherein the electrically conductive layer provides electrical coupling between the segment of the thermoelectric material and the second thermally conductive layer across the gap, and wherein the second thermally conductive layer is free of the segment of thermoelectric material between the electrically conductive layer and the second thermally conductive layer.

23. A thermoelectric structure according to claim 1 wherein the first and second thermally conductive layers have respective first and second surfaces facing in opposite directions, wherein the thermoelectric element bridges the gap between the first and second surfaces of the first and second thermally conductive layers.
